(19) United States
(12) Patent Application Publication
(10) Pub. No.: US 2024/0389227 A1
(43) Pub. Date: Nov. 21, 2024

(54) RADIATION-SENSITIVE COMPOSITION FOR FORMING INSULATION FILM, RESIN FILM HAVING PATTERN, AND SEMICONDUCTOR CIRCUIT BOARD

(71) Applicant: JSR CORPORATION, Tokyo (JP)

(72) Inventors: Ryouji TATARA, Minato-ku, Tokyo (JP); Hirokazu ITOU, Minato-Ku, Tokyo (JP); Taku OGAWA, Minato-ku, Tokyo (JP); Shin-Ya NAKAFUJI, Minato-ku, Tokyo (JP); Shoma ANABUKI, Minato-ku, Tokyo (JP)

(73) Assignee: JSR CORPORATION, Tokyo (JP)

(21) Appl. No.: 18/284,345

(22) PCT Filed: Mar. 22, 2022
(86) PCT No.: PCT/JP2022/013159

§ 371 Date: Sep. 27, 2023

(30) Foreign Application Priority Data
Apr. 2, 2021 (JP) 2021-063606
Apr. 2, 2021 (JP) 2021-063607

(51) Int. Cl. H05K 1/03; G03F 7/004; G03F 7/038; G03F 7/32

(52) U.S. Cl. CPC H05K 1/0326; G03F 7/0045; G03F 7/0382; G03F 7/325; H05K 1/0346; H05K 1/0373; H05K 2201/0209

(57) ABSTRACT

A radiation-sensitive composition for forming an insulation film, includes: at least one polyfunctional compound (A) selected from the group consisting of a polyfunctional maleimide compound (A-1) and a polyfunctional styryl compound (A-2); a polymer (B) having a group Y that reacts with a maleimide group in the polyfunctional maleimide compound (A-1) or a styryl group in the polyfunctional styryl compound (A-2); and a photopolymerization initiator (C). The group Y is represented by Formula (Y1). In Formula (Y1), R^{Y1} represents a hydrogen atom or an alkyl group having 1 to 5 carbon atoms, L^{Y1} represents a single bond, an alkanediyl group having 1 to 5 carbon atoms, —C(O)O—, —NH—C(O)—NH—, or a group obtained by a combination thereof, and * represents a position bonded to a main chain or a side chain of the polymer (B).

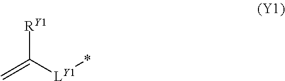

### TECHNICAL FIELD

The present invention relates to a radiation-sensitive composition for forming an insulation film, a resin film having a pattern, and a semiconductor circuit board.

### BACKGROUND ART

Recently, in accordance with high performance of information terminal devices and dramatic progress in network technology, a frequency of an electric signal handled in the field of information and communications has been increased in order to achieve a higher speed and a larger capacity. In a semiconductor circuit board used in such a device, measures have been taken to reduce a transmission loss, which is a problem in transmitting and processing high-frequency electric signals.

As a measure against such a problem, an insulation film used in a semiconductor circuit board is required to have a low dielectric constant and a low dielectric loss tangent in a high-frequency region (for example, see Patent Literature 1).

### CITATION LIST

### Patent Literature

Patent Literature 1: JP 2020-29504 A

### SUMMARY OF INVENTION

### Technical Problem

A package technology using a silicon interposer or a fan-out type package technology using a mold substrate, for example, has been proposed to increase a density and performance of a semiconductor circuit board. However, since a substrate material and an insulation film have different coefficients of linear thermal expansion, warpage deformation may easily occur due to, for example, a temperature change in a manufacturing process of the semiconductor circuit board or the use environment of the information terminal device. In a case where the insulation film has small elongation properties, the insulation film cannot withstand the warp deformation and is thus damaged. In addition, also in an environmental load test (for example, PCT test) assuming a use environment of the information terminal device, high reliability capable of maintaining elongation properties is required.

Furthermore, the insulation film used in the semiconductor circuit board is used between fine pitch electrode pads or between wirings. Therefore, a composition for forming a resin film having a pattern such as an insulation film (hereinafter, also referred to as a “patterned resin film”) is required to have a photolithography property capable of patterning by exposure and development.

The present invention has been made to solve the above problems, and an object of the present invention is to provide a radiation-sensitive composition for forming an insulation film that can form a resin film that is excellent in elongation properties at a low dielectric constant and a low dielectric loss tangent and has high reliability, and has a photolithography property, to provide a patterned resin film that is excellent in elongation properties at a low dielectric constant and a low dielectric loss tangent and has high reliability, and a method for producing the same, and to provide a semiconductor circuit board including a patterned resin film that is excellent in elongation properties at a low dielectric constant and a low dielectric loss tangent and has high reliability.

### Solution to Problem

The present inventors have conducted intensive studies in order to solve the above problems. As a result, the present inventors have found that the above problems can be solved by a radiation-sensitive composition for forming an insulation film containing a specific polyfunctional compound, a specific polymer, and a photopolymerization initiator, thereby completing the present invention. Examples of aspects of the present invention are shown below.

[1] A radiation-sensitive composition for forming an insulation film, containing:
at least one polyfunctional compound (A) selected from a polyfunctional maleimide compound (A-1) and a polyfunctional styryl compound (A-2);
a polymer (B) having a group Y that reacts with a maleimide group in the polyfunctional maleimide compound (A-1
) or a styryl group in the polyfunctional styryl compound (A-2); and
   a photopolymerization initiator (C),
   in which the polymer (B) is a polymer having a repeating structural unit represented by the following Formula (a2), and
   the group Y is represented by the following Formula (Y1).

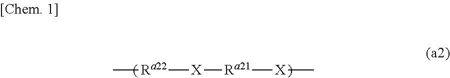

[In Formula (a2), two X's each independently represent a single bond, an oxygen atom, a sulfur atom, an amide bond, —NH—C(O)—NH—, or —SO₂—, and at least one X represents an oxygen atom, a sulfur atom, an amide bond, —NH—C(O)—NH—, or —SO₂—,
R^{a21} represents a divalent hydrocarbon group or a divalent group in which a hydrogen atom in the divalent hydrocarbon group is substituted with a functional group other than a heterocyclic ring,
R^{a22} represents a divalent hydrocarbon group, a divalent group in which a hydrogen atom in the divalent hydrocarbon group is substituted with a functional group other than a heterocyclic ring, or a heterocyclic ring-containing group, and
R^{a21} and R^{a22} may have the group Y.]

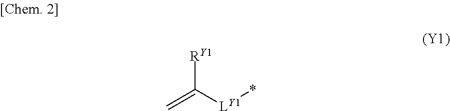

[In Formula (Y1), R^{Y1} represents a hydrogen atom or an alkyl group having 1 to 5 carbon atoms, L^{Y1} represents a single bond, an alkanediyl group having 1 to 5 carbon atoms, —C(O)O—, —NH—C(O)—NH—, or a group obtained by a combination thereof, and * represents a position bonded to a main chain or a side chain constituting the polymer (B).]

[2] A radiation-sensitive composition for forming an insulation film, containing:
a polyfunctional maleimide compound (A-1);
a polymer (B) having a group Y that reacts with a maleimide group in the polyfunctional maleimide compound (A-1); and
a photopolymerization initiator (C),
in which the polymer (B) is a polymer having a repeating structural unit represented by the following Formula (a2), and
the group Y is represented by the following Formula (Y1).

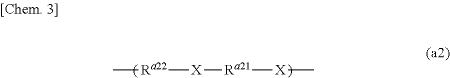

[In Formula (a2), two X's each independently represent a single bond, an oxygen atom, a sulfur atom, an amide bond, —NH—C(O)—NH—, or —SO₂—, and at least one X represents an oxygen atom, a sulfur atom, an amide bond, —NH—C(O)—NH—, or —SO₂—,
R^{a21} represents a divalent hydrocarbon group or a divalent group in which a hydrogen atom in the divalent hydrocarbon group is substituted with a functional group other than a heterocyclic ring,
R^{a22} represents a divalent hydrocarbon group, a divalent group in which a hydrogen atom in the divalent hydrocarbon group is substituted with a functional group other than a heterocyclic ring, or a heterocyclic ring-containing group, and
R^{a21} and R^{a22} may have the group Y.]

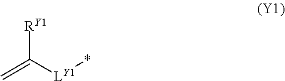

[In Formula (Y1), R^{Y1} represents a hydrogen atom or an alkyl group having 1 to 5 carbon atoms, L^{Y1} represents a single bond, an alkanediyl group having 1 to 5 carbon atoms, —C(O)O—, —NH—C(O)—NH—, or a group obtained by a combination thereof, and * represents a position bonded to a main chain or a side chain constituting the polymer (B).]

[3] The radiation-sensitive composition for forming an insulation film according to [2], further containing a polyfunctional styryl compound (A-2).

[4] The radiation-sensitive composition for forming an insulation film according to any one of [1] to [3], in which the polyfunctional maleimide compound (A-1) has three or more maleimide groups.

[5] The radiation-sensitive composition for forming an insulation film according to any one of [1] to [4], in which the polyfunctional maleimide compound (A-1) has a phenolic hydroxyl group.

[6] The radiation-sensitive composition for forming an insulation film according to any one of [1] to [5], in which the polymer (B) is a polyimide, a polyimide precursor, a polybenzoxazole, a polybenzoxazole precursor, or a polyphenylene ether.

[7] The radiation-sensitive composition for forming an insulation film according to any one of [1] to [6], in which the polymer (B) has the group Y at a terminal thereof.

[8] The radiation-sensitive composition for forming an insulation film according to any one of [1] to [7], in which
R^{a21} is an arylene group.

[9] The radiation-sensitive composition for forming an insulation film according to any one of [1] to [8], in which R^{a22} is a divalent group obtained by removing two hydrogen atoms from pyrimidine, or an arylene group.

[10] A method for producing a resin film having a pattern, the method including: a step (1) of forming, on a substrate, a coating film of the radiation-sensitive composition for forming an insulation film according to any one of [1] to [9]; a step (2) of selectively exposing the coating film; and a step (3) of developing the exposed coating film with a developer containing an organic solvent.

[11] A resin film having a pattern obtained by curing the radiation-sensitive composition for forming an insulation film according to any one of [1] to [9].

[12] A semiconductor circuit board including the resin film having a pattern according to [11].

### Advantageous Effects of Invention

According to the present invention, it is possible to provide a radiation-sensitive composition for forming an insulation film that can form a resin film that is excellent in elongation properties at a low dielectric constant and a low dielectric loss tangent and has high reliability, and has a photolithography property, to provide a patterned resin film that is excellent in elongation properties at a low dielectric constant and a low dielectric loss tangent and has high reliability, and a method for producing the same, and to provide a semiconductor circuit board including a patterned resin film that is excellent in elongation properties at a low dielectric constant and a low dielectric loss tangent and has high reliability.

### DESCRIPTION OF EMBODIMENTS

Hereinafter, the present invention will be described in detail.

### [Radiation-Sensitive Composition for Forming Insulation Film]

A radiation-sensitive composition for forming an insulation film of the present invention (hereinafter, also referred to as a “composition of the present invention”) contains at least one polyfunctional compound (A) selected from a polyfunctional maleimide compound (A-1) and a polyfunctional styryl compound (A-2), a polymer (B) having a group Y that reacts with a maleimide group in the polyfunctional maleimide compound (A) or a styryl group in the polyfunctional styryl compound (A-2), and a photopolymerization initiator (C).

### <Polyfunctional Compound (A)>

The polyfunctional compound (A) used in the present invention is at least one selected from a polyfunctional maleimide compound (A-1) and a polyfunctional styryl compound (A-2).

### <<Polyfunctional Maleimide Compound (A-1)>>

The polyfunctional maleimide compound (A-1) used in the present invention is a compound having two or more maleimide groups and preferably three or more maleimide groups in the molecule, and an upper limit of the number of maleimide groups is preferably 10 and more preferably 4.

The maleimide group is a group that directly acts on a group Y to be described below during, for example, photocrosslinking or thermal crosslinking, and for example, it is considered that the following reaction proceeds.

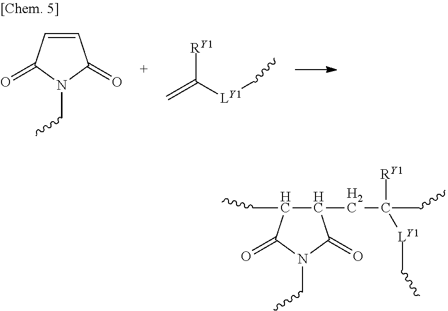

Therefore, when the composition of the present invention contains the polyfunctional maleimide compound (A-1), for example, a crosslinked structure can be formed in the form of consuming the group Y in the polymer (B) during exposure, and a cured film having high reliability can be obtained.

Examples of the polyfunctional maleimide compound (A-1) include a compound represented by Formula (A1) (hereinafter, also referred to as a “crosslinking maleimide compound (A1)”). By using the crosslinking maleimide compound (A1), a cured film formed using the composition of the present invention can further exhibit the effect of improving the elongation properties or reliability.

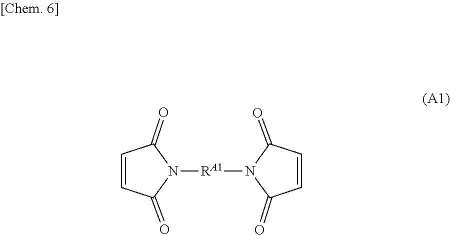

In Formula (A1), R^{A1} is an organic group, and examples of the organic group include an aromatic ring-containing group such as an alkanediyl group or an arylene group, an alicyclic ring-containing group such as a cycloalkylene group, and a group derived from a dimer acid obtained from an unsaturated fatty acid.

The number of carbon atoms of the alkanediyl group is usually 1 to 20 and preferably 2 to 10.

Examples of the aromatic ring-containing group and the alicyclic ring-containing group include an arylene group having 6 to 20 carbon atoms, a cycloalkylene group having 3 to 20 carbon atoms, a group represented by —Z—X^{A1}—Z—, a group represented by —Z—O—Z—X^{A1}—Z—O—Z—, and a group represented by —R^{A2}—Z—R^{A2}—. Z represents a benzene ring or a cyclohexane ring, and may each independently have one or two or more substituents such as an alkyl group having 1 to 10 carbon atoms and an alkoxy group having 1 to 6 carbon atoms. X^{A1} is a direct bond, —O—, —SO₂—, an alkanediyl group having 1 to 10 carbon atoms, or an alicyclic ring-containing group having 3 to 20 carbon atoms. R^{A2} is an alkanediyl group having 1 to 10 carbon atoms.

Examples of the alkanediyl group include a methylene group, an ethanediyl group, a propanediyl group, a hexanediyl group, an octanediyl group, a nonanediyl group, and a decanediyl group. Examples of the arylene group include a phenylene group, a methylphenylene group, a t-butylphenylene group, and a naphthylene group. Examples of the cycloalkylene group include a cyclobutanediyl group, a cyclopentanediyl group, and a cyclohexanediyl group. Examples of the alkyl group include a methyl group, an ethyl group, and a propyl group. Examples of the alkoxy group include a methoxy group and an ethoxy group. Examples of the alicyclic ring include a cyclohexane ring and a tricyclodecane ring.

Specific examples of the crosslinking maleimide compound (A1) include N,N′-ethylenebismaleimide, N,N′-hexamethylenebismaleimide, N,N′-(2,2,4-trimethylhexane)bismaleimide (“BMI-TMH” manufactured by Daiwa Kasei Industry Co., Ltd.), N,N′-p-phenylenebismaleimide, N,N′-m-phenylenebismaleimide, (“BMI-3000” manufactured by Daiwa Kasei Industry Co., Ltd.), N,N′-4-methyl-1,3-phenylenebismaleimide (“BMI-7000” manufactured by Daiwa Kasei Industry Co., Ltd.), N,N′-2,4-tolylenebismaleimide, N,N′-2,6-tolylenebismaleimide, N,N′-p-xylylenebismaleimide, N,N′-m-xylylenebismaleimide, N,N′-(1,3-dimethylenecyclohexane)bismaleimide, N,N′-(1,4-dimethylenecyclohexane)bismaleimide, N,N′-(4,4′-biphenylene)bismaleimide, N,N′-(4,4′-diphenylmethane)bismaleimide (“BMI-1000” manufactured by Daiwa Kasei Industry Co., Ltd.), N,N′-(3,3′-dimethyl-5,5′-diethyl-4,4′-diphenylmethane)bismaleimide (“BMI-5100” manufactured by Daiwa Kasei Industry Co., Ltd.), N,N′-(4,4′-dicyclohexylmethane)bismaleimide, N,N′-(4,4′-diphenyloxy)bismaleimide, N,N′-(4,4′-diphenylsulfone)bismaleimide, and a compound represented by the following formula (“BMI-4000” manufactured by Daiwa Kasei Industry Co., Ltd.).

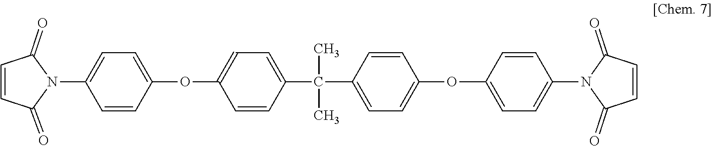 [SMILES: CC(C)(c1ccc(Oc2ccc(N3C(=O)C=CC3=O)cc2)cc1)c1ccc(Oc2ccc(N3C(=O)C=CC3=O)cc2)cc1]

Other specific examples of the crosslinking maleimide compound (A1) include bis[4-(4-maleimidophenoxy)phenyl]methane, 2,2-bis[4-(4-maleimidophenoxy)phenyl]propane, bis[4-(4-maleimidophenoxy)phenyl]octane, bis[4-(4-maleimidophenoxy)phenyl]decane, bis[4-(4-maleimidophenoxy)phenyl]cyclohexane, and bis[4-(4-maleimidophenoxy)phenyl]-tricyclo-[5.2.1.0^{2.6}]decane.

At least one hydrogen atom in the benzene ring and the cyclohexane ring in the exemplary compound may be each independently substituted with a C₁₋₁₀ alkyl group. Examples of the alkyl group include a methyl group, an ethyl group, and a propyl group.

In addition, a bismaleimide compound in which both terminals of a polyoxyalkylenediamine are blocked with maleic anhydride can also be used. Examples thereof include a bismaleimide compound in which both terminals of a polyoxyalkylenediamine are blocked with maleic anhydride, a bismaleimide compound in which both terminals of a polyoxypropylenediamine are blocked with maleic anhydride, and a bismaleimide compound in which both terminals of a polyoxybutylenediamine are blocked with maleic anhydride.

As the polyfunctional maleimide compound (A-1), a polyfunctional maleimide compound, which is a compound represented by Formula (0) described in WO 2019/167359 A, in which at least two R^{1A}'s are maleimide groups having 4 to 30 carbon atoms which may have a substituent, can also be used. In addition, various polyfunctional maleimide compounds obtained by the method described in, for example, [0207] to [0255] of WO 2019/167359 A can also be used.

As aldehydes used in the method described in WO 2019/167359 A, for example, a dialdehyde compound having a phenolic hydroxyl group as described below can be used. Thus, a polyfunctional maleimide compound having a phenolic hydroxyl group can be obtained.

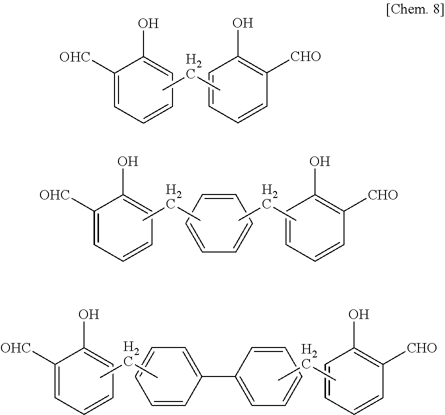

Examples of the polyfunctional maleimide (A-1) containing a polyfunctional maleimide compound having a phenolic hydroxyl group obtained by the method described in WO 2019/167359 A include a compound (A-M1) represented by the following Formula (M1) and a multimer of the compound (A-M1).

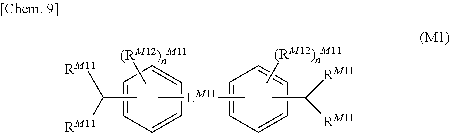

In Formula (M1), R^{M11}'s each independently represent a hydroxyl group or a monovalent organic group having a maleimide group,
R^{M12} represents a hydroxyl group, an alkoxy group, or a thiol group,
L^{M11} represents a single bond, an alkanediyl group having 1 to 5 carbon atoms, a divalent aromatic ring-containing group, or a group obtained by a combination thereof,
n^{M11} represents an integer of 1 to 4, and
two or more of the plurality of R^{M11}'s are monovalent organic groups having a maleimide group.

Examples of the alkanediyl group having 1 to 5 carbon atoms include a methylene group, an ethanediyl group, a propanediyl group, a butanediyl group, and a pentanediyl group.

Examples of the divalent aromatic ring-containing group include the same groups as those exemplified as the aromatic ring-containing group in Formula (A1).

Examples of the monovalent organic group having a maleimide group include groups represented by the following Formulas (M31) to (M33).

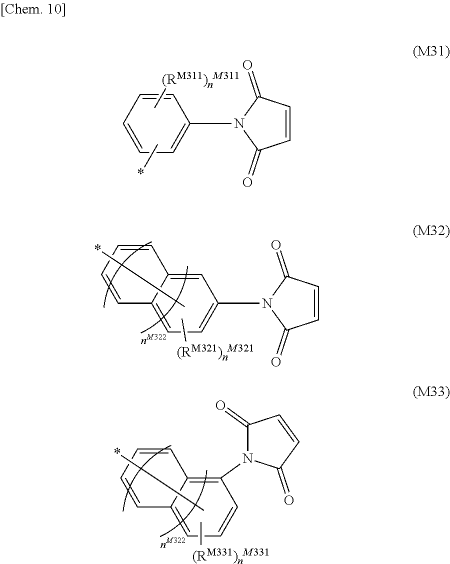

In Formulas (M31), (M32), and (M33), * represents a bond to the carbon atom to which R^{M11} in Formula (M1) is bonded.

In Formula (M31), R^{M311} represents an alkyl group having 1 to 5 carbon atoms, an alkoxy group having 1 to 5 carbon atoms, a cycloalkyl group having 3 to 10 carbon atoms, a cycloalkoxy group having 3 to 10 carbon atoms, an aryl group having 6 to 15 carbon atoms, an aryloxy group having 6 to 15 carbon atoms, or a hydroxyl group, and n^{M311} represents an integer of 0 to 4.

In Formula (M32), R^{M}321 represents an alkyl group having 1 to 5 carbon atoms, an alkoxy group having 1 to 5 carbon atoms, a cycloalkyl group having 3 to 10 carbon atoms, a cycloalkoxy group having 3 to 10 carbon atoms, an aryl group having 6 to 15 carbon atoms, an aryloxy group having 6 to 15 carbon atoms, or a hydroxyl group, n^{M321} represents an integer of 0 to 4, and n^{M322} represents an integer of 0 or 1.

In Formula (M33), R^{M331} represents an alkyl group having 1 to 5 carbon atoms, an alkoxy group having 1 to 5 carbon atoms, a cycloalkyl group having 3 to 10 carbon atoms, a cycloalkoxy group having 3 to 10 carbon atoms, an aryl group having 6 to 15 carbon atoms, an aryloxy group having 6 to 15 carbon atoms, or a hydroxyl group, n^{M331} represents an integer of 0 to 4, and n^{M332} represents an integer of 0 or 1.

Examples of the group represented by Formula (M31) include an N-phenylmaleimide group, a 3-ethyl-5-methyl-4-maleimidephenyl group, a 3-methoxy-4-maleimidephenyl group, and a 3-phenyl-4-maleimidephenyl group.

Examples of the multimer of the compound (A-M1) include a compound (A-M2) represented by the following Formula (M2).

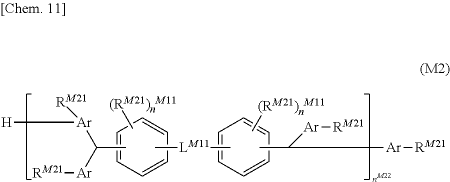

In Formula (M2), R^{M21}'s each independently represent a hydrogen atom or a maleimidephenyl group,
R^{M12}, L^{M11}, and n^{M11} have the same meanings as R^{M12}, L^{M11}, and n^{M11} in Formula (M1) and n^{M22} represents an integer of 1 to 10, and
two or more of the plurality of R^{M21}'s are maleimide groups.

As the polyfunctional maleimide compound (A-1), a commercially available product may be used. Examples of commercially available products of the polyfunctional maleimide compound (A-1) include “BMI-2000” and “BMI-2300” represented by the following Formula (M41) manufactured by Daiwa Kasei Industry Co., Ltd., “MIR-3000” and “MIR-5000” represented by the following Formula (M42) manufactured by Nippon Kayaku Co., Ltd., and “SLK-3000”, “SLK-6895”, “SLK-1500”, “SLK-2500”, and “SLK-6100” manufactured by Shin-Etsu Chemical Co., Ltd.

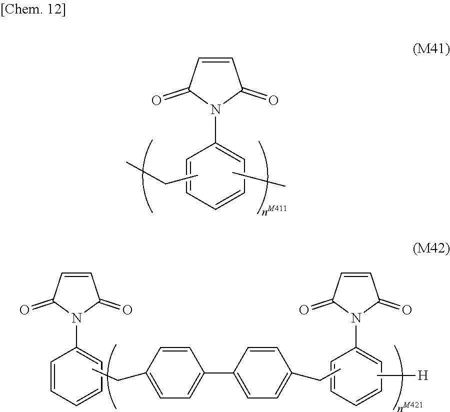

In Formula (M41), n^{M411} represents the number of repeating units, and in a case of BMI-2000, n^{M411}≈2, and in a case of BMI-2300, n^{M411}≈2 to 5. In addition, in Formula (M42), n^{M421} represents the number of repeating units, and in a case of MIR-3000, n^{M421}≈2 to 5.

The polyfunctional maleimide compounds (A-1) can be used alone, or two or more thereof can be used in combination.

### <<Polyfunctional Styryl Compound (A-2)>>

The polyfunctional styryl compound (A-2) used in the present invention is a compound having two or more styryl groups and preferably three or more styryl groups in the molecule, and an upper limit of the number of styryl groups is preferably 10 and more preferably 4.

The styryl group is a group that directly acts on a group Y to be described below during, for example, photocrosslinking or thermal crosslinking, and for example, it is considered that the following reaction proceeds.

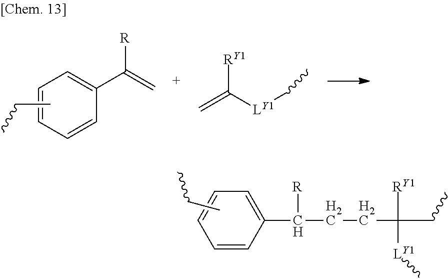

R in the formula represents a hydrogen atom and a hydrocarbon group having 1 to 5 carbon atoms.

Therefore, when the composition of the present invention contains the polyfunctional styryl compound (A-2), for example, a crosslinked structure can be formed in the form of consuming the group Y in the polymer (B) during exposure, and a cured film having high reliability can be obtained.

Examples of the polyfunctional styryl compound (A-2) include a compound represented by Formula (A2) (hereinafter, also referred to as a “crosslinking styryl compound (A2)”). By using the crosslinking styryl compound (A2), a cured film formed using the composition of the present invention can further exhibit the effect of improving the elongation properties or reliability.

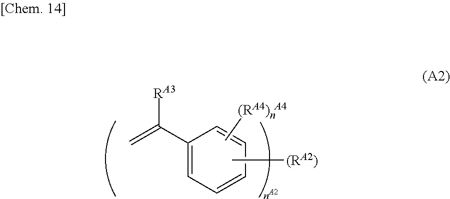

In Formula (A2), n^{A2} is an integer of 2 or more, preferably 2 to 10, and more preferably 2 to 6, and R^{A2} is an n^{A2} valent organic group in which n^{A2} hydrogen atoms are removed from an organic compound. Examples of the organic group include an aliphatic hydrocarbon compound, an aromatic hydrocarbon compound, a heterocyclic compound, and a group obtained by removing n^{A2} hydrogen atoms from a compound in which two or more compounds thereof are linked by a single bond, —O—, —S—, —SO₂—, —NR^{N1}—, —CO—, —COO—, or —CONH—. R^{N1} is a hydrogen atom or a group obtained by removing one hydrogen atom from the organic compound. R^{A3} is a hydrogen atom or a hydrocarbon group having 1 to 5 carbon atoms. R^{A4} is an alkyl group having 1 to 10 carbon atoms. n^{A4} is an integer of 0 to 4. Note that, in a case where there are a plurality of R^{A3}'s, R^{A4}'s, and R^{N1}'s in one molecule, the groups may be the same as or different from each other.

The number of carbon atoms of the aliphatic hydrocarbon compound is usually 1 to 20 and preferably 2 to 10.

Examples of the aromatic hydrocarbon compound include aromatic hydrocarbon compounds having 6 to 20 carbon atoms such as benzene, naphthalene, anthracene, and fluorene. Examples of the heterocyclic compound include a nitrogen-containing heterocyclic ring such as pyrrole, imidazole, pyrazole, pyridine, pyrimidine, triazine, pyridazine, or pyrazine, an oxygen-containing heterocyclic ring such as furan or pyran, a sulfur-containing heterocyclic ring such as thiophene or thioxanthene, an oxazole containing a plurality of heteroatoms, and a thiazole.

Specific examples of the polyfunctional styryl compound (A2) include divinylbenzene and compounds represented by the following formulas.

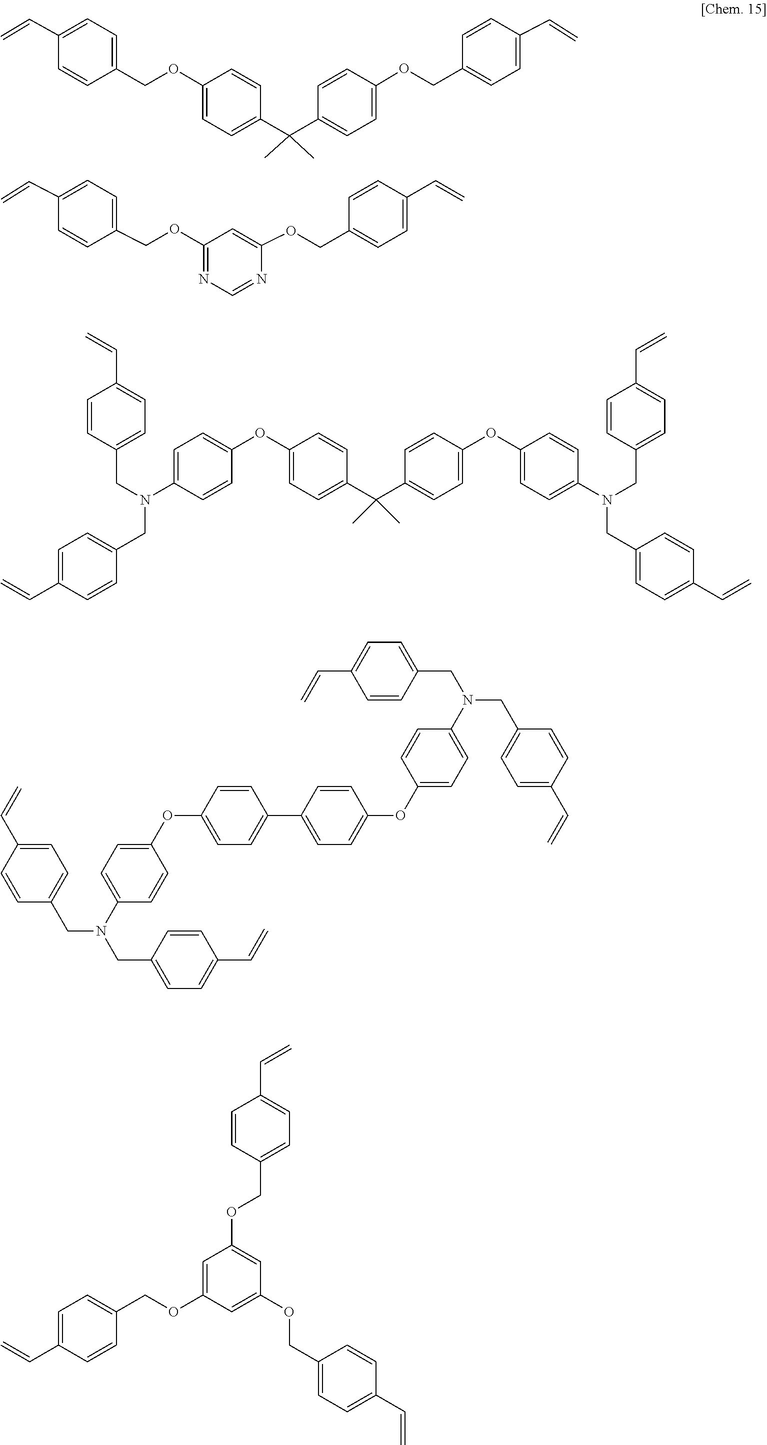

At least one hydrogen atom in the benzene ring in the exemplary compound may be each independently substituted with an alkyl group having 1 to 10 carbon atoms. Examples of the alkyl group include a methyl group, an ethyl group, and a propyl group.

The polyfunctional styryl compounds (A-2) can be used alone, or two or more thereof can be used in combination. In addition, the polyfunctional styryl compound (A-2) is also preferably used in combination with the polyfunctional maleimide compound (A-1). By using the polyfunctional styryl compound (A-2) and the polyfunctional maleimide compound (A-1) in combination, a residual film ratio (ratio at which a patterned thin film appropriately remains) is improved.

In the composition of the present invention, the total content of the polyfunctional compound (A) is usually 0.1 to 200 parts by mass, preferably 1 to 100 parts by mass, and more preferably 5 to 50 parts by mass, with respect to 100 parts by mass of the polymer (B). When the content of the polyfunctional compound (A) is within the above range, a cured film obtained from the composition of the present invention is excellent in both photolithographic properties and chemical resistance and crack resistance.

### <Polymer (B)>

The polymer (B) used in the present invention has a group Y that reacts with a maleimide group in the polyfunctional maleimide compound (A-1) or a styryl group in the polyfunctional styryl compound (A-2) (hereinafter, may also be referred to as a “reactive group Y”), and is a polymer having a repeating structural unit represented by the following Formula (a2) (hereinafter, also referred to as a “repeating structural unit (a2)”), and the group Y is represented by the following Formula (Y1). The polymer (B) may be a polymer having one repeating structural unit (a2) or may be a polymer having two or more repeating structural units (a2).

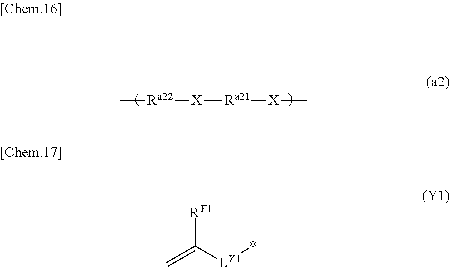

The meanings of the respective symbols in Formulas (a2) and (Y1) are as follows.

### <<X>>

Two X's in Formula (a2) each independently represent an oxygen atom, a sulfur atom, an amide bond, —NH—C(O)—NH—, or —SO₂—, and at least one X is an oxygen atom, a sulfur atom, an amide bond, —NH—C(O)—NH—, or —SO₂—. Among them, an oxygen atom, an amide bond, and —NH—C(O)—NH— are preferable because the composition of the present invention can be used to form a patterned resin film that is excellent in elongation properties at a low dielectric constant and a low dielectric loss tangent, and the polymer (B) is excellent in solubility in an organic solvent and storage stability.

<<R^{a21} and R^{a22>>}

In Formula (a2), R^{a21} represents a divalent hydrocarbon group or a divalent group in which a hydrogen atom in the divalent hydrocarbon group is substituted with a functional group other than a heterocyclic ring (hereinafter, also referred to as a “divalent substituted hydrocarbon group”). R^{a21} may have the group Y.

In Formula (a2), R^{a22} represents a divalent hydrocarbon group, a divalent group in which a hydrogen atom in the divalent hydrocarbon group is substituted with a functional group other than a heterocyclic ring (a “divalent substituted hydrocarbon group”), or a heterocyclic ring-containing group. R^{a22} may have the group Y.

R^{a21} is preferably a divalent hydrocarbon group, and R^{a22} is preferably a heterocyclic ring-containing group or a divalent hydrocarbon group that does not have the reactive group, and is more preferably a heterocyclic ring-containing group that does not have the reactive group. Such an aspect is preferable because a dipole moment in a minor axis direction of the polymer (B) (a direction perpendicular to a main chain direction of the polymer (B)) decreases, and the composition of the present invention can be used to form a patterned resin film that is excellent in elongation properties at a low dielectric constant and a low dielectric loss tangent.

### (Divalent Hydrocarbon Group)

Examples of the divalent hydrocarbon group in R^{a21} and R^{a22} include an alkanediyl group, an alicyclic ring-containing hydrocarbon group, and an aromatic ring-containing hydrocarbon group, and among them, an aromatic ring-containing hydrocarbon group is preferable because a patterned resin film that is excellent in heat resistance can be formed using the composition of the present invention. Note that a hydrocarbon group having both an alicyclic ring and an aromatic ring are classified into an aromatic ring-containing hydrocarbon group.

The number of carbon atoms of the alkanediyl group is usually 1 to 30 and preferably 1 to 20. Examples of the alkanediyl group include a linear alkanediyl group such as a methylene group, an ethylene group, a propane-1,3-diyl group, a butane-1,4-diyl group, a hexane-1,6-diyl group, an octane-1,8-diyl group, or a decane-1,10-diyl group; and a branched alkanediyl group obtained by adding one or a plurality of side chains containing an alkyl group having 1 to 4 carbon atoms to the exemplified linear alkanediyl group.

The number of carbon atoms of the alicyclic ring-containing hydrocarbon group is usually 3 to 30 and preferably 5 to 20. Examples of an alicyclic ring, that is, an aliphatic hydrocarbon ring include a monocyclic aliphatic hydrocarbon ring such as a cyclobutane ring, a cyclopentane ring, a cyclohexane ring, a cycloheptane ring, or a cyclodecane ring; and a polycyclic aliphatic hydrocarbon ring such as a norbornane ring, a norbornene ring, an adamantane ring, a tricyclo[5.2.1.0^{2,6}]decane ring, or a tricyclo[5.2.1.0^{2,6}]heptane ring. The alicyclic ring-containing hydrocarbon group can have the aliphatic hydrocarbon ring, for example, as a monovalent group (for example, a cycloalkyl group) or a divalent group (for example, a cycloalkanediyl group); and examples thereof include a group in which at least one hydrogen atom in an alkanediyl group is substituted with a monovalent aliphatic hydrocarbon ring, and a group in which a divalent aliphatic hydrocarbon ring and an alkanediyl group are linked.

Examples of the aromatic ring-containing hydrocarbon group include an arylene group and a divalent group represented by —R³—Ar—R³—. In the formula, Ar is an arylene group; and R³'s are each independently an alkanediyl group (the number of carbon atoms of the alkanediyl group is usually 1 to 6.).

In the present specification, the arylene group means a divalent hydrocarbon group having one or more aromatic rings, that is, aromatic hydrocarbon rings, and having two bonds in the aromatic hydrocarbon ring. In a case where the arylene group has a plurality of aromatic hydrocarbon rings, the two bonds may be present in the same aromatic hydrocarbon ring or may be present in different aromatic hydrocarbon rings.

Examples of the aromatic hydrocarbon ring contained in the arylene group include a benzene ring; and a benzo fused ring such as a naphthalene ring, an anthracene ring, a tetracene ring, or a pentacene ring. The number of carbon atoms of the arylene group is preferably 6 to 50 and more preferably 6 to 30.

Examples of the arylene group include a phenylene group, a naphthalenediyl group, an anthracenediyl group, a tetracenediyl group, a pentacenediyl group, and divalent groups represented by the following Formulas (a1-1) to (a1-4). Each aromatic hydrocarbon ring (for example, a benzene ring) contained in these groups can have one or more substituents, and examples of the substituent include an alkyl group having 1 to 30 carbon atoms, a cycloalkyl group, an aryl group, and an aralkyl group. In a case where the aromatic hydrocarbon ring has two or more substituents, the substituents may be the same as or different from each other.

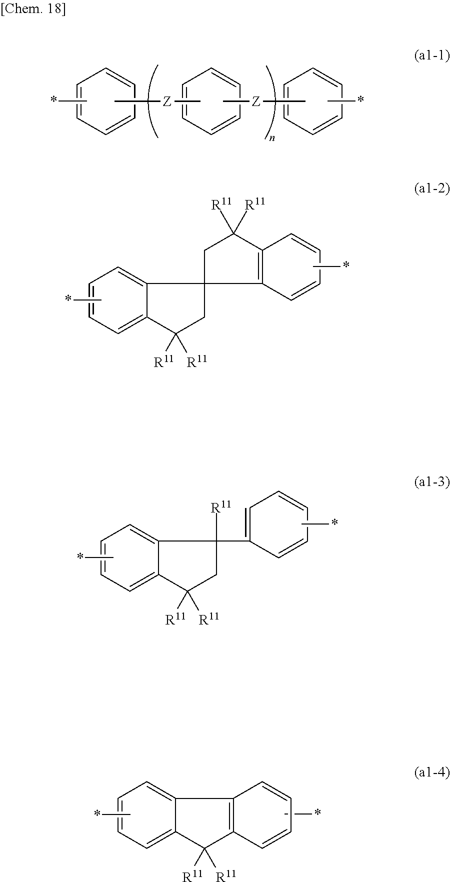

In Formulas (a1-1) to (a1-4), * is a bond.

In Formula (a1-1), Z's are each independently a single bond or a divalent hydrocarbon group having 1 to 20 carbon atoms, and a divalent hydrocarbon group having 1 to 20 carbon atoms is preferable. n is an integer of 0 to 3. Examples of the divalent hydrocarbon group having 1 to 20 carbon atoms include an alkanediyl group such as a methylene group, an ethylene group, a 1,1-dimethylmethane-1,1-diyl group, or a decane-1,1-diyl group; an aryl group-substituted alkanediyl group such as a diphenylmethylene group; a cycloalkanediyl group such as a cyclohexane-1,1-diyl group or a 3,3,5-trimethylcyclohexane-1,1-diyl group; and a phenylene group and a fluorenylidene group.

In Formulas (a1-2) and (a1-4), R¹¹'s are each independently a hydrogen atom or an alkyl group, and preferably an alkyl group having 1 to 10 carbon atoms.

### (Divalent Substituted Hydrocarbon Group)

The divalent substituted hydrocarbon group in R^{a21} and R^{a22} is a group in which a functional group other than the reactive group and the heterocyclic ring is introduced into the divalent hydrocarbon group. Examples of the functional group include a group selected from a halogen atom, a nitro group, a cyano group, an allyl group, and a vinyl group and other than the reactive group. In addition, it is preferable that the functional group is not a functional group having high polarity such as a hydroxyl group from the viewpoint of low dielectric properties.

### (Heterocyclic Ring-Containing Group)

Examples of the heterocyclic ring-containing group in R^{a22} include a cyclic imide group, an alicyclic imide ring-containing group having a structure in which a cyclic imide group is fused to an alicyclic hydrocarbon group, and an aromatic imide ring-containing group having a structure in which a cyclic imide group is fused to a heteroaromatic ring-containing group and an aromatic ring. Examples of the cyclic imide group and the alicyclic imide ring-containing group having a structure in which a cyclic imide group is fused to an alicyclic hydrocarbon group include groups represented by the following formulas.

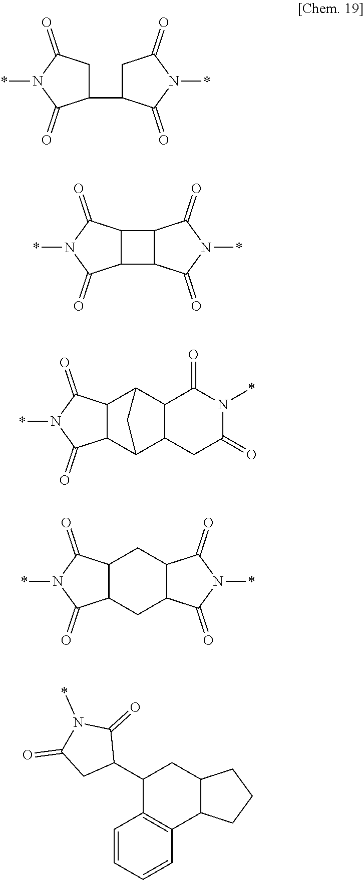

In the formulas, * is a bond.

Examples of the heteroaromatic ring include an N-containing aromatic ring such as a pyrimidine ring, a pyrazine ring, a pyridazine ring, a pyridine ring, a pyrrole ring, or a pyrazole ring; an O-containing aromatic ring such as a furan ring; an S-containing aromatic ring such as a thiophene ring; an N- and O-containing aromatic ring such as a benzoxazole ring or an isoxazole ring; and an N- and S-containing aromatic ring such as an isothiazole ring. Examples of the aromatic imide ring-containing group include a phthalimide group.

The heterocyclic ring can have one or more, for example, one or two substituents bonded to the heterocyclic ring, and examples of the substituents include a group selected from a monovalent hydrocarbon group having 1 to 20 carbon atoms, such as a halogen atom, an alkyl group, a cycloalkyl group, an aryl group, an allyl group, and a vinyl group, a monovalent halogenated hydrocarbon group having 1 to 20 carbon atoms, a nitro group, and a cyano group, and other than the reactive group. In addition, it is preferable that the functional group is not a functional group having high polarity such as a hydroxyl group from the viewpoint of low dielectric properties. The number of carbon atoms of the hydrocarbon group and the halogenated hydrocarbon group is preferably 1 to 3. In a case where the heterocyclic ring has two or more substituents, the substituents may be the same as or different from each other.

Among the heteroaromatic ring-containing groups, a divalent group obtained by removing two hydrogen atoms from a benzoxazole ring-containing group, an aromatic imide ring-containing group, pyrimidine, pyrazine, or pyridazine is preferable, a divalent group obtained by removing two hydrogen atoms from pyrimidine, pyrazine, or pyridazine is more preferable, and a divalent group obtained by removing two hydrogen atoms from pyrimidine is particularly preferable, since a patterned resin film that is excellent in a low dielectric constant and a low dielectric loss tangent can be formed using the composition of the present invention.

### <<R^{Y1>>}

In Formula (Y1), R^{Y1} represents a hydrogen atom or an alkyl group having 1 to 5 carbon atoms. Examples of the alkyl group having 1 to 5 carbon atoms include a methyl group, an ethyl group, an n-propyl group, an iso-propyl group, an n-butyl group, a sec-butyl group, a tert-butyl group, an n-pentyl group, a sec-pentyl group, and a 3-pentyl group.

R^{Y1} is preferably a hydrogen atom, a methyl group, or an ethyl group, and more preferably a hydrogen atom or a methyl group.

### <<L^{Y1>>}

In Formula (Y1), L^{Y1} represents a single bond, an alkanediyl group having 1 to 5 carbon atoms, —C(O)O—, —NH—C(O)—NH—, or a group obtained by a combination thereof. Examples of the alkanediyl group having 1 to 5 carbon atoms include a methylene group, an ethylene group, a propanediyl group, a butanediyl group, and a pentanediyl group.

L^{Y1} is preferably a single bond, a methylene group, an ethylene group, —C(O)O—, —NH—C(O)—NH—, —C(O)O—(CH₂)_{y}—, —C(O)O—(CH₂)_{y}—OC(O)—, or —C(O)O—(CH₂)_{y}—NH—C(O)—NH— (y represents an integer of 1 to 3), and more preferably a single bond, —C(O)O—(CH₂)₂—OC(O)—, or —C(O)O—(CH₂)₂—NH—C(O)—NH—.

In Formula (Y1), * represents a position bonded to a main chain or a side chain constituting the polymer (B).

### <<Preferred Configuration>>

In Formula (a2), R^{a21} is preferably an aromatic ring-containing hydrocarbon group, and more preferably an arylene group. In addition, in Formula (a2), R^{a22} is preferably an aromatic ring-containing hydrocarbon group or a heterocyclic ring-containing group, and more preferably an arylene group or a divalent group obtained by removing two hydrogen atoms from pyrimidine.

When the polymer (B) has the preferred configuration described above, a patterned resin film that is excellent in a low dielectric constant and a low dielectric loss tangent can be formed using the composition of the present invention.

Examples of a preferred aspect of the polymer (B) include a polyimide, a polyimide precursor, a polybenzoxazole, a polybenzoxazole precursor, and a polyphenylene ether.

The polymer (B) is preferably a linear polymer having the group Y at a terminal of a polymer chain, and particularly preferably a linear polymer represented by the following Formula (BB) because a patterned resin film that is excellent in elongation properties can be formed using the composition of the present invention.

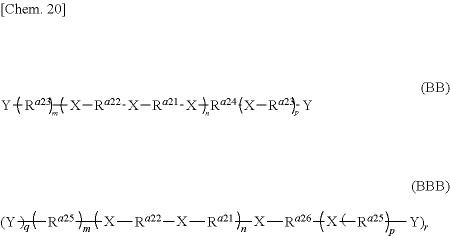

In Formula (BB), R^{a21}, R^{a22}, and X have the same meanings as the same symbols in Formula (a2), and R^{a23} and R^{a24} have the same meanings as R^{a21} and R^{a22}, respectively. Y means the reactive group Y. n represents that a structure in ( ) is a repeating structural unit, that is, a repeating structural unit (a2) is bonded like . . . —R^{a22}—X—R^{a21}—X—R^{a22}—X—R^{a21}—X— . . . . The repeating structural units (a2) may be used alone or in combination of two or more thereof. m and p each independently represent an integer of 0 or 1 or more, preferably an integer of 0 or 1 to 10, more preferably an integer of 0 or 1 to 5. Note that, for example, when p is an integer of 2 or more, —(X—R^{a23})ₚ— represents that a structure in ( ) is a repeating structural unit by binding to each other like —X—R^{a23}—X—R^{a23}— . . . , and the repeating structural units may be used alone or in combination of two or more thereof. The same applies to a case where m is 2 or more.

In Formula (BBB), R^{a21}, R^{a22}, and X have the same meanings as the same symbols in Formula (a2), and Y, n, m, and p have the same meanings as the same symbols in Formula (BB). R^{a25} and R^{a26} have the same meanings as R^{a21} and R^{a22}, respectively, and in a case where the reactive group Y is bonded, a valence corresponding to the number of reactive groups Y is employed. q and r each independently represent an integer of 2 or more, preferably an integer of 2 to 8, and more preferably an integer of 2 to 4.

### <<Configuration of Polymer (B)>>

In the polymer (B), a content ratio of the repeating structural unit (a2) is usually 30 mass % or more, preferably 50 mass % or more, still more preferably 70 mass % or more, and further still more preferably 90 mass % or more in 100 mass % of the polymer (B). According to such an aspect, the composition of the present invention is excellent in resolution, and the resin film obtained using the composition of the present invention tends to be excellent in elongation properties at a low dielectric constant and a low dielectric loss tangent. The content ratio of the repeating structural unit (a2) can be measured by ¹³C-NMR.

The group Y contained in the polymer (B) can be subjected to qualitative analysis or quantitative analysis by combining, for example, a matrix-assisted laser desorption/ionization method, a three-dimensional nuclear magnetic resonance method, and a titration method.

A weight average molecular weight (Mw) of the polymer (B) measured by a gel permeation chromatography method is usually 1,000 to 200,000, preferably 2,000 to 100,000, and more preferably 5,000 to 100,000 in terms of polystyrene from the viewpoint of the resolution of the composition of the present invention and the elongation properties of the resin film obtained using the composition of the present invention. Details of the method for measuring Mw are as described in Examples.

The polymers (B) may be used alone or in combination of two or more thereof. A lower limit of a content ratio of the polymer (B) in 100 mass % of a solid content of the composition of the present invention is usually 20 mass %, preferably 40 mass %, and more preferably 60 mass %, and an upper limit thereof is usually 99 mass % and preferably 95 mass %. When the content ratio of the polymer (B) is above the lower limit and below the upper limit, there is a tendency that a radiation-sensitive composition for forming an insulation film capable of forming a patterned resin film having high resolution is obtained. Note that the solid content refers to all components other than an organic solvent (E) described below that can be contained in the composition of the present invention.

### <<Method for Producing Polymer (B)>>

The polymer (B) can be produced, for example, by polycondensation. More specifically, the polymer (B) can be produced using a bisphenol compound and a dihalogen compound as monomers and an alkali metal compound as a polymerization catalyst when X is an oxygen atom, using a bisthiol compound and a dihalogen compound as monomers and an alkali metal compound as a polymerization catalyst when X is a sulfur atom, and using a diamine compound, an acid dianhydride, and an acid dichloride as monomers when X is an amide bond. Examples of a reactive group Y modifier include a compound having one functional group identical to the functional group that reacts at the time of polycondensation of the monomer in the molecule and having one or more groups Y.

Hereinafter, as an example of the polymer (B), a polymer (B11) in which X is an oxygen atom in Formula (a2) and an α-methylstyryl group is a reactive group Y will be described. The polymer (B11) can be obtained, for example, by polymerizing at least a phenol compound (bb1) having two phenolic hydroxyl groups, a halogen compound (bb2) having two halogen atoms, and a reactive group Y modifier (bb3) having one phenolic hydroxyl group and one α-methylstyryl group.

The reactive group Y modifier can be represented by the following Formula (YM).

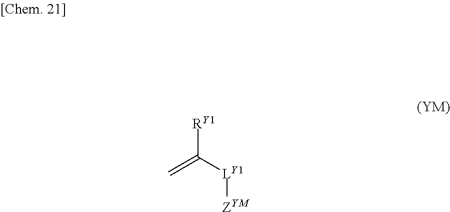

In Formula (YM), R^{Y1} and L^{Y1} have the same meaning as R^{Y1} and L^{Y1} in Formula (Y1), and Z^{YM} is not particularly limited as long as it is a group capable of reacting with a functional group at the terminal of the main chain or the side chain of the polymer (B), and examples thereof include an isocyanate group, an acid anhydride group, and a chlorine atom in a case where the terminal of the polymer (B) is an amino group, include a chlorine atom in a case where the terminal of the main chain or the side chain of the polymer (B) is a phenolic hydroxyl group, include an amino group and a hydroxyl group in a case where the terminal of the main chain or the side chain of the polymer (B) is a carboxyl group or an acid anhydride group, and include a hydroxyl group and an amino group in a case where the terminal of the main chain or the side chain of the polymer (B) is a chlorinated heteroaromatic ring.

In synthesis of the polymer (B11), for example, the phenol compound (bb1), the halogen compound (bb2), and the reactive group Y modifier (bb3) are polymerized in an appropriate polymerization solvent in the presence of an alkali metal compound. The amount of the phenol compound (bb1) used is usually less than 100 mol and preferably 90.0 to 99.9 mol with respect to 100 mol of the halogen compound (bb2). The amount of the reactive group Y modifier (bb3) used is usually less than 50 mol and preferably 0.1 to 20.0 mol with respect to 100 mol of the halogen compound (bb2).

Examples of the alkali metal compound include a carbonate, a hydrogencarbonate, and a hydroxide of an alkali metal such as lithium, sodium, or potassium. Among them, a carbonate and a hydroxide are preferable, and potassium carbonate, sodium carbonate, potassium hydroxide, and sodium hydroxide are more preferable.

The polymer (B) in which X is other than an oxygen atom in Formula (a2) can be produced, for example, by known polycondensation.

### <Photopolymerization Initiator (C)>

The composition of the present invention contains a photopolymerization initiator (C). The photopolymerization initiator (C) is a compound that generates an active species that promotes a crosslinking reaction between the group Y and the polyfunctional maleimide compound (A) in the polymer (B) by exposure with radiation such as visible light, ultraviolet light, far ultraviolet light, electron beam, or X-ray. The photopolymerization initiators (C) may be used alone or in combination of two or more thereof.

It is considered that the crosslinking reaction between the group Y and the polyfunctional maleimide compound (A) in the polymer (B) is promoted by the exposure treatment of the coating film formed using the composition of the present invention, a crosslinked structure is formed in an exposed portion, and solubility in a developer is reduced.

The photopolymerization initiator (C) is preferably a photosensitive radical polymerization initiator that generates radicals by irradiation with light, and examples thereof include an oxime-based compound, an organic halogenated compound, an oxydiazole compound, a carbonyl compound, a ketal compound, a benzoin compound, an acridine compound, an organic peroxide compound, an azo compound, a coumarin compound, an azide compound, a metallocene compound, a hexaarylbiimidazole compound, an organic boric acid compound, a disulfonic acid compound, an onium salt compound, and an acylphosphine (oxide) compound. Among them, a photoradical polymerization initiator having an oxime-based compound, and particularly an oxime ester structure is preferable from the viewpoint of sensitivity.

The photoradical polymerization initiator having an oxime ester structure may have geometric isomers due to the double bond of the oxime, but these are not distinguished, and both are included in the photoradical polymerization initiator (C).

Examples of the photoradical polymerization initiator having an oxime ester structure include photoradical polymerization initiators described in WO 2010/146883 A, JP 2011-132215 A, JP 2008-506749 A, JP 2009-519904 A, and JP 2009-519991 A.

Specific examples of the photoradical polymerization initiator having an oxime ester structure include N-benzoyloxy-1-(4-phenylsulfanylphenyl)buta-1-one-2-imine, N-ethoxycarbonyloxy-1-phenylpropan-1-one-2-imine, N-benzoyloxy-1-(4-phenylsulfanylphenyl)octan-1-one-2-imine, N-acetoxy-1-[9-ethyl-6-(2-methylbenzoyl)-9H-carbazol-3-yl]ethane-1-imine, N-acetoxy-1-[9-ethyl-6-{2-methyl-4-(3,3-dimethyl-2,4-dioxacyclopentanylmethyloxy)benzoyl}-9H-carbazol-3-yl]ethane-1-imine, ethanone, 1-[9-ethyl-6-(2-methylbenzoyl)-9H-carbazol-3-yl]-, and 1-(O-acetyloxime).

These photopolymerization initiators (C) may be used alone or in combination of two or more thereof. A lower limit of a content of the photopolymerization initiator (C) with respect to 100 parts by mass of the polymer (B) in the composition of the present invention is usually 0.01 parts by mass, preferably 0.1 parts by mass, and more preferably 0.5 parts by mass, and an upper limit thereof is usually 30 parts by mass, preferably 20 parts by mass, and more preferably 10 parts by mass. When the content of the photopolymerization initiator (C) is above the lower limit, curing of the exposed portion becomes sufficient, and the heat resistance of the patterned resin film is easily improved. When the content of the photopolymerization initiator (C) is below the upper limit, transparency to light used for exposure is not deteriorated, and a patterned resin film having high resolution is easily obtained.

### <Surfactant (D)>

The composition of the present invention may contain a surfactant (D) from the viewpoint of improving coating properties, defoaming properties, and leveling properties. The surfactant is not particularly limited, and a known nonionic surfactant, fluorine-based surfactant, and silicone-based surfactant can be used.

Examples of a commercially available surfactant include fluorosurfactants commercially available under the names such as BM-1000 and BM-1100 (manufactured by BM Chemie), Megafac F142D, Megafac F172, Megafac F173, and Megafac F183 (manufactured by Dainippon Ink & Chemicals Co., Ltd.), Fluorad FC-135, Fluorad FC-170C, Fluorad FC-430, and Fluorad FC-431 (manufactured by Sumitomo 3M Ltd.), Surflon S-112, Surflon S-113, Surflon S-131, Surflon S-141, and Surflon S-145 (manufactured by Asahi Glass Co., Ltd.), SH-28PA, SH-190, SH-193, SZ-6032, and SF-8428 (manufactured by Toray Silicone Co., Ltd.), and NBX-15 (manufactured by Neos Corporation); silicone-based surfactants commercially available under the names such as KL-245 and KL-270 (manufactured by Kyoeisha Chemical Co., Ltd.), and SH28PA (manufactured by Dow Corning Toray Co., Ltd.); and nonionic surfactants commercially available under the names such as NONION S-6, NONION 0-4, PLONON 201, and PLONON 204 (manufactured by NOF CORPORATION), EMULGEN A-60, EMULGEN A-90, and EMULGEN A-500 (manufactured by Kao Corporation), and KL-600 (manufactured by Kyoeisha Chemical Co., Ltd.).

The surfactants (D) may be used alone or in combination of two or more thereof. The surfactant (D) is used in a range of an amount of preferably 5 parts by mass or less and more preferably 0.01 to 2 parts by mass with respect to 100 parts by mass of the polymer (B).

### <Organic Solvent (E)>

The composition of the present invention contains an organic solvent (E). By using the organic solvent (E), handleability of the composition of the present invention can be improved, and a viscosity and storage stability can be adjusted.

The organic solvent (E) is not particularly limited as long as it is an organic solvent capable of dissolving or dispersing each component such as the polyfunctional maleimide compound (A), the polymer (B), or the photopolymerization initiator (C). Examples of the organic solvent (E) include a ketone solvent, an alcohol solvent, an ether solvent, an ester solvent, an amide solvent, and a hydrocarbon solvent.

Examples of the ketone solvent include a chain ketone solvent such as acetone, methyl ethyl ketone, methyl-n-propyl ketone, methyl-n-butyl ketone, diethyl ketone, methyl-iso-butyl ketone, 2-heptanone (methyl amyl ketone), ethyl-n-butyl ketone, methyl-n-hexyl ketone, di-iso-butyl ketone, or trimethylnonanone; a cyclic ketone solvent such as cyclopentanone, cyclohexanone, cycloheptanone, cyclooctanone, or methylcyclohexanone; and 2,4-pentanedione, acetonylacetone, and acetophenone.

Examples of the alcohol solvent include an aliphatic monoalcohol solvent having 1 to 18 carbon atoms such as 4-methyl-2-pentanol or n-hexanol; an alicyclic monoalcohol solvent having 3 to 18 carbon atoms such as cyclohexanol; a polyhydric alcohol solvent having 2 to 18 carbon atoms such as 1,2-propylene glycol; and a polyhydric alcohol partial ether solvent having 3 to 19 carbon atoms such as propylene glycol monomethyl ether.

Examples of the ether solvent include a dialkyl ether solvent such as diethyl ether, dipropyl ether, dibutyl ether, dipentyl ether, diisoamyl ether, dihexyl ether, or diheptyl ether; a cyclic ether solvent such as tetrahydrofuran or tetrahydropyran; and an aromatic ring-containing ether solvent such as diphenyl ether or anisole.

Examples of the ether solvent include a monocarboxylic acid ester solvent such as n-butyl acetate or ethyl lactate; a polyhydric alcohol carboxylate solvent such as propylene glycol acetate; a polyhydric alcohol partial ether carboxylate solvent such as propylene glycol monomethyl ether acetate; a polyvalent carboxylic acid diester solvent such as diethyl oxalate; a lactone solvent such as γ-butyrolactone or δ-valerolactone; and a carbonate solvent such as dimethyl carbonate, diethyl carbonate, ethylene carbonate, or propylene carbonate.

Examples of the amide solvent include a cyclic amide solvent such as N,N′-dimethylimidazolidinone or N-methyl-2-pyrrolidone; and a chain amide solvent such as N-methylformamide, N,N-dimethylformamide, N,N-diethylformamide, acetamide, N-methylacetamide, N,N-dimethylacetamide, or N-methylpropionamide.

Examples of the hydrocarbon solvent include an aliphatic hydrocarbon solvent having 5 to 12 carbon atoms such as n-pentane or n-hexane; and an aromatic hydrocarbon solvent having 6 to 16 carbon atoms such as toluene or xylene.

The organic solvent (E) is preferably at least one selected from a ketone solvent, an ester solvent, and an amide solvent.

The composition of the present invention can contain one or two or more organic solvents (E). A content of the organic solvent (E) in the composition of the present invention is an amount at which a solid content concentration in the composition is usually 10 to 50 mass %.

### <Other Components>

The composition of the present invention may contain other components in addition to the components described above as long as the objects and characteristics of the present invention are not impaired. Examples of the other components include a crosslinking agent other than the polyfunctional maleimide compound (A); a polymer other than the polymer (B); and additives such as a low-molecular-weight phenol compound, an adhesion aid, crosslinked fine particles, a leveling agent, a sensitizer, an inorganic filler, and a quencher.

### <Method for Preparing Radiation-Sensitive Composition for Forming Insulation Film>

The composition of the present invention can be prepared by uniformly mixing the respective components constituting the composition of the present invention. In addition, in order to remove foreign matter, after uniformly mixing the respective components, the obtained mixture can be filtered with a filter.

### <Characteristics of Radiation-Sensitive Composition for Forming Insulation Film>

A patterned resin film obtained by curing the composition of the present invention is excellent in elongation properties. This is presumed to be due to the following reason. Since the polymer (B) has the reactive group substantially only at the terminal of the polymer chain, when the composition of the present invention is crosslinked, crosslinking occurs so that the polymer chain in the polymer (B) is chain-extended, and thus a crosslinking density is low. On the other hand, it is considered that many polymer chains are entangled with each other, and thus, a gentle interaction between polymer chains occurs. Therefore, it is presumed that the elongation properties of the obtained patterned resin film can be improved.

In addition, the patterned resin film obtained using the composition of the present invention has a low dielectric constant and a low dielectric loss tangent. In order to obtain such low dielectric properties, it is preferable that the dipole moment in the minor axis direction (direction perpendicular to the main chain direction of the polymer) in the repeating structural unit of the polymer to be used is small, and the polymer (B) is suitable from this viewpoint. Furthermore, as described above, since crosslinking occurs mainly at the terminal of the polymer chain rather than in the repeating structural unit (a2) of the polymer (B), it is presumed that a change in the dipole moment is small through the formation of the patterned resin film.

A coating film formed using the composition of the present invention can be developed with a developer containing an organic solvent as described below. When an aqueous solution containing an alkaline compound is used as the developer, in order to impart alkali developability to the polymer, a functional group having high polarity and moisture absorbability such as a phenolic hydroxyl group may be introduced into the repeating structural unit of the polymer. In this case, the amount of the functional group having high polarity introduced into the polymer is large, and therefore, it is considered that the dielectric constant and the dielectric loss tangent are high. In the present invention, since a developer containing an organic solvent can be used for forming the patterned resin film, the amount of the functional group having high polarity introduced into the polymer can be reduced, and therefore, a low dielectric constant and a low dielectric loss tangent can be achieved.

### [Method for Producing Resin Film Having Pattern]

A method for producing a resin film having a pattern (patterned resin film) of the present invention includes: a step (1) of forming a coating film of the composition of the present invention on a substrate; a step (2) of selectively exposing the coating film; and a step (3) of developing the exposed coating film with a developer containing an organic solvent.

### <Step (1)>

In the step (1), the composition of the present invention is usually applied onto a substrate so that a thickness of a finally obtained patterned resin film is, for example, 0.1 to 100 μm. The substrate after application of the composition is usually heated at 50 to 140° C. for 10 to 360 seconds using an oven or a hot plate. As such, a coating film formed using the composition of the present invention is formed on a substrate.

Examples of the substrate include a silicon wafer, a compound semiconductor wafer, a wafer with a metal thin film, a glass substrate, a quartz substrate, a ceramic substrate, an aluminum substrate, and a substrate having a semiconductor chip on a surface of each of these substrates. Examples of the application method include a dipping method, a spraying method, a bar coating method, a roll coating method, a spin coating method, a curtain coating method, a gravure printing method, a silk screen method, and an inkjet method.

### <Step (2)>

In the step (2), the coating film is selectively exposed using, for example, a contact aligner, a stepper, or a scanner. The expression “selectively” specifically means via a photomask on which a predetermined mask pattern is formed.

Examples of the exposure light include ultraviolet rays and visible rays, and light having a wavelength of 200 to 500 nm (for example, i-line (365 nm)) is usually used. An exposure dose by exposure light varies depending on, for example, the type and blending ratio of each component in the composition of the present invention and a thickness of the coating film, and the exposure dose is usually 100 to 1,500 mJ/cm².

In addition, in order to sufficiently perform the crosslinking reaction, it is preferable to perform a heat treatment (post-exposure baking) after exposure. The condition of the heat treatment after exposure varies depending on, for example, the content of each component in the composition of the present invention and the thickness of the coating film, and is usually 70 to 250° C. and preferably 80 to 200° C. for about 1 to 60 minutes.

### <Step (3)>

In the step (3), the exposed coating film is developed with a developer containing an organic solvent, and an unexposed portion is dissolved and removed to form a desired patterned resin film on the substrate. Examples of the development method include a shower development method, a spray development method, an immersion development method, and a paddle development method. The development condition is usually 20 to 40° C. for about 1 to 10 minutes.

The developer contains one or two or more organic solvents. Examples of the developer include an organic solvent such as a ketone solvent, an alcohol solvent, an ether solvent, an ester solvent, an amide solvent, or a hydrocarbon solvent, and a liquid containing the organic solvent. Specific examples of these organic solvents include a compound exemplified as the organic solvent (E). Among them, the organic solvent (E) is preferably at least one selected from a ketone solvent, an ester solvent, and an amide solvent. Examples of components other than the organic solvent in the developer include water, silicone oil, and a surfactant.

A content ratio of the organic solvent in the developer is preferably 80 mass % or more, more preferably 90 mass % or more, still more preferably 95 mass % or more, and particularly preferably 99 mass % or more.

Note that, after the exposed coating film is developed using a developer containing an organic solvent to form a patterned resin film, the patterned resin film can be washed with, for example, water and dried.

The shape of the pattern in the patterned resin film is not particularly limited as long as it has an irregularity structure, and examples thereof include a line-and-space pattern, a dot pattern, a hole pattern, and a lattice pattern.

### <Step (4)>

The method for producing a patterned resin film of the present invention can include, after the step (3), a step (4) of sufficiently curing the patterned resin film by a heat treatment (post-baking), as necessary, in order to sufficiently exhibit characteristics as an insulation film. The curing conditions are not particularly limited, and depending on the application of the patterned resin film, for example, heating is performed at a temperature of 100 to 250° C. for about 30 minutes to 10 hours.

The patterned resin film obtained by the production method of the present invention can be preferably used as an insulation film (examples: a surface protective film, an interlayer insulation film, or a planarization film) of a semiconductor circuit board.

### [Semiconductor Circuit Board]

By using the composition of the present invention, a semiconductor circuit board including the resin film (patterned resin film) having a pattern described above can be produced. Since the semiconductor circuit board includes a patterned resin film formed using the composition of the present invention described above, and preferably includes a patterned insulation film such as a surface protective film, an interlayer insulation film, or a planarization film, the semiconductor circuit board is useful as a high-frequency circuit board.

### EXAMPLES

Hereinafter, the present invention will be described in more detail based on Examples, but the present invention is not limited to these Examples. In the following description of Examples and others, unless otherwise specified, “part(s)” is used to mean “part(s) by mass”.

### <Synthesis of Polymer (B)>

A weight average molecular weight (Mw) of the polymer (B) obtained in the following synthesis example was measured by a gel permeation chromatography method under the following conditions.
Column: product name “TSKgelα-M” (manufactured by Tosoh Corporation)
Solvent: N-methyl-2 pyrrolidone
Temperature: 40° C.
Detection method: refractive index method
Standard substance: polystyrene
GPC apparatus: apparatus name “HLC-8320-GPC” manufactured by Tosoh Corporation

### [Synthesis Example 1] Synthesis of Polymer (B1)

Into a four-necked flask, 177.65 mmol of 4,6-dichloropyrimidine as a halogen compound, 153.00 mmol of bisphenol A and 17.00 mmol of 1,1-bis(4-hydroxyphenyl)-3,3,5-trimethylcyclohexane as phenol compounds, 17.00 mmol of 4-hydroxy-α-methylstyrene as a reactive group Y modifier, 239.83 mmol of potassium carbonate as an alkali metal compound, and N-methyl-2 pyrrolidone (0.5 g with respect to 1 mmol of the total amount of the halogen compound, the phenol compounds, and the reactive group Y modifier) as a polymerization solvent were charged. After the inside of the flask was replaced with nitrogen, the contents of the flask were heated at 130° C. for 6 hours, and water generated during the heating was removed from the Dean-Stark tube as needed. After the contents of the flask were cooled to room temperature, the precipitated solid was separated by filtration, methanol was added to the filtrate, the precipitated solid was washed with methanol, and these solids were dried, thereby obtaining a polymer (B1). The obtained polymer (B1) was analyzed by, for example, ¹³C-NMR and revealed that it was a polymer having a structure represented by Formula (B1). The weight average molecular weight (Mw) of the polymer (B1) was 14,000.

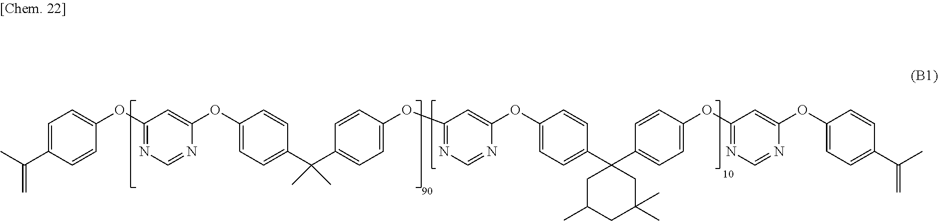

### [Synthesis Example 2] Synthesis of Polymer (B2)

Into a four-necked flask, 153.46 mmol of 4,4′-(hexafluoroisopropylidene)diphthalic anhydride as an acid dianhydride, 170.52 mmol of 2,2-bis[4-(4-aminophenoxy)phenyl]propane as a diamine, and N-methyl-2 pyrrolidone (2.0 g with respect to 1 mmol of the total amount of the acid dianhydride and the diamine) as a polymerization solvent were charged. After the inside of the flask was replaced with nitrogen, the contents of the flask were heated at 40° C. for 4 hours and then further heated at 180° C. for 4 hours. As a reactive group Y modifier, 170.52 mmol of 3-isopropenyl-α,α-dimethylbenzyl isocyanate was added, and the contents of the flask were heated at 70° C. for 4 hours. After the contents of the flask were cooled to room temperature, methanol was added, the precipitated solid was washed with methanol, and these solids were dried, thereby obtaining a polymer (B2). The obtained polymer (B2) was analyzed by, for example, ¹³C-NMR and revealed that it was a polymer having a structure represented by Formula (B2). The weight average molecular weight (Mw) of the polymer (B2) was 24,000.

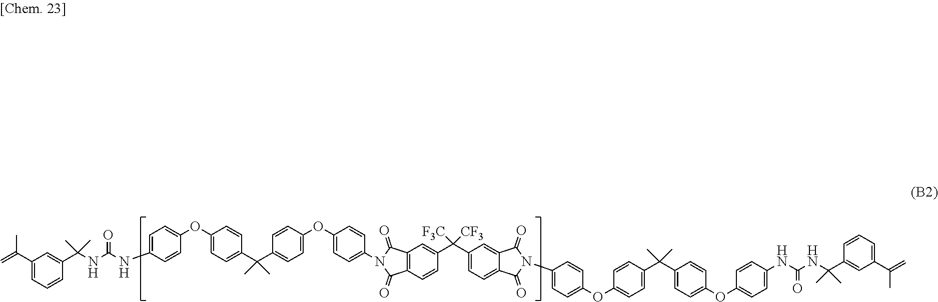

### [Synthesis Example 3] Synthesis of Polymer (B3)

Into a four-necked flask, 157.31 mmol of pyromellitic anhydride as an acid dianhydride, 174.79 mmol of 4,4′-diaminodiphenyl ether as a diamine, and N-methyl-2 pyrrolidone (1.0 g with respect to 1 mmol of the total amount of the acid dianhydride and the diamine) as a polymerization solvent were charged. After the inside of the flask was replaced with nitrogen, the contents of the flask were heated at 40° C. for 4 hours. After the contents of the flask were cooled to room temperature, 349.58 mmol of N,N-dimethylformamide dimethyl acetal was added, and the contents of the flask were stirred at room temperature for 4 hours. As a reactive group Y modifier, 174.79 mmol of 3-isopropenyl-α,α-dimethylbenzyl isocyanate was added, and the contents of the flask were heated at 70° C. for 4 hours. After the contents of the flask were cooled to room temperature, methanol was added, the precipitated solid was washed with methanol, and these solids were dried, thereby obtaining a polymer (B3). The obtained polymer (B3) was analyzed by, for example, ¹³C-NMR and revealed that it was a polymer having a structure represented by Formula (B3). The weight average molecular weight (Mw) of the polymer (B3) was 21,000.

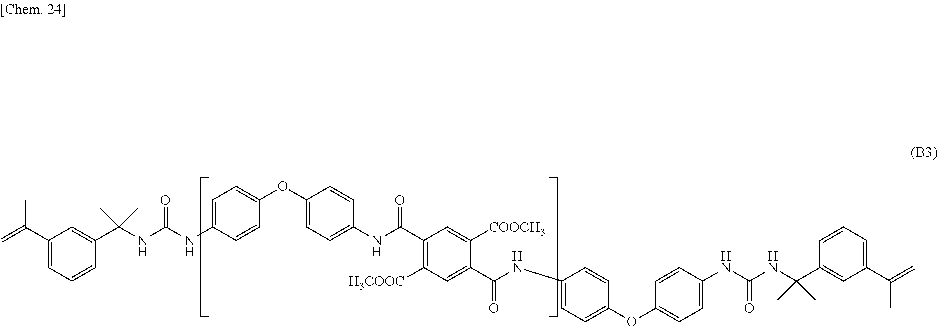

### [Synthesis Example 4] Synthesis of Polymer (B4)

Into a four-necked flask, 162.23 mmol of 4,4′-(hexafluoroisopropylidene)diphthalic anhydride as an acid dianhydride, 175.39 mmol of 2,2-bis[4-(4-aminophenoxy)phenyl]propane as a diamine, and N-methyl-2 pyrrolidone (2.0 g with respect to 1 mmol of the total amount of the acid dianhydride and the diamine) as a polymerization solvent were charged. After the inside of the flask was replaced with nitrogen, the contents of the flask were heated at 40° C. for 4 hours and then further heated at 180° C. for 4 hours. After the contents of the flask were cooled to room temperature, as a reactive group Y modifier, 105.23 mmol of 2-isocyanatoethyl methacrylate was added, and the contents of the flask was heated at 40° C. for 4 hours. After the contents of the flask were cooled to room temperature, methanol was added, the precipitated solid was washed with methanol, and these solids were dried, thereby obtaining a polymer (B4). The obtained polymer (B4) was analyzed by, for example, ¹³C-NMR and revealed that it was a polymer having a structure represented by Formula (B4). The weight average molecular weight (Mw) of the polymer (B4) was 27,000.

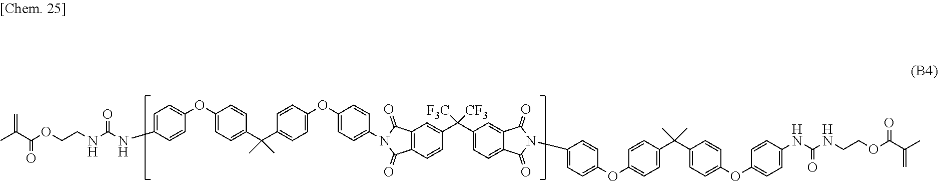

### [Synthesis Example 5] Synthesis of Polymer (B5)

Into a four-necked flask, 173.04 mmol of 4,4′-(4,4′-isopropylidenediphenoxy)diphthalic anhydride as an acid dianhydride, 346.07 mmol of 2-hydroxyethyl methacrylate as a reactive group Y modifier, 346.07 mmol of pyridine as a base, and N-methyl-2 pyrrolidone (2.0 g with respect to 1 mmol of the total amount of the acid dianhydride and the diamine) as a polymerization solvent were charged. After the inside of the flask was replaced with nitrogen, the contents of the flask were heated at 40° C. for 4 hours. After the contents of the flask were cooled to room temperature, as a diamine, 181.69 mmol of 2,2-bis[4-(4-aminophenoxy)phenyl]propane was added, under ice cooling, 346.07 mmol of dicyclohexylcarbodiimide (DCC) was added, and the contents of the flask were stirred at room temperature for 4 hours. The precipitated solid was separated by filtration, methanol was added to the filtrate, the precipitated solid was washed with methanol, and these solids were dried, thereby obtaining a polymer (B5). The obtained polymer (B5) was analyzed by, for example, ¹³C-NMR and revealed that it was a polymer having a structure represented by Formula (B5). The weight average molecular weight (Mw) of the polymer (B5) was 20,000.

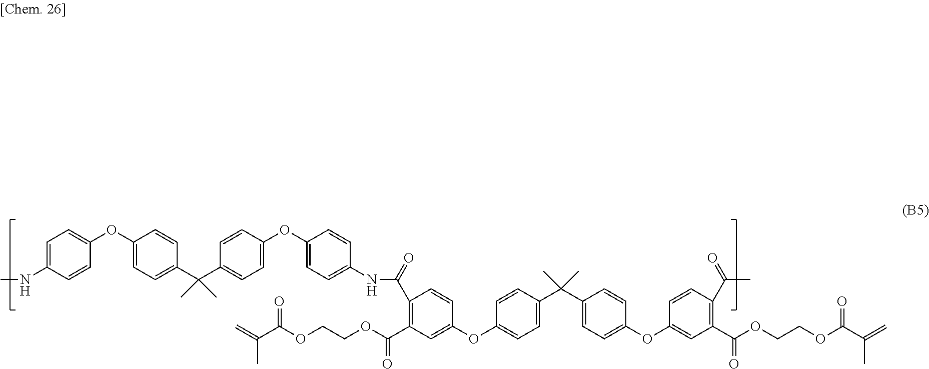

### [Synthesis Example 6] Synthesis of Polymer (B6)

Into a four-necked flask, 171.56 mmol of 4,6-dichloropyrimidine as a halogen compound, 150.00 mmol of bisphenol A and 37.50 mmol of 1,1-bis(4-hydroxyphenyl)-3,3,5-trimethylcyclohexane as phenol compounds, 231.61 mmol of potassium carbonate as an alkali metal compound, and N-methyl-2 pyrrolidone (0.5 g with respect to 1 mmol of the total amount of the halogen compound, the phenol compounds, and the reactive group Y modifier) as a polymerization solvent were charged. After the inside of the flask was replaced with nitrogen, the contents of the flask were heated at 130° C. for 6 hours, and water generated during the heating was removed from the Dean-Stark tube as needed. After the contents of the flask were cooled to room temperature, 150.00 mmol of 4-(chloromethyl) styrene as a reactive group Y modifier and 150.00 mmol of potassium carbonate as an alkali metal compound were added, and the contents of the flask was heated at 80° C. for 4 hours. After the contents of the flask were cooled to room temperature, the precipitated solid was separated by filtration, methanol was added to the filtrate, the precipitated solid was washed with methanol, and these solids were dried, thereby obtaining a polymer (B6). The obtained polymer (B6) was analyzed by, for example, ¹³C-NMR and revealed that it was a polymer having a structure represented by Formula (B6). The weight average molecular weight (Mw) of the polymer (B6) was 12,000.

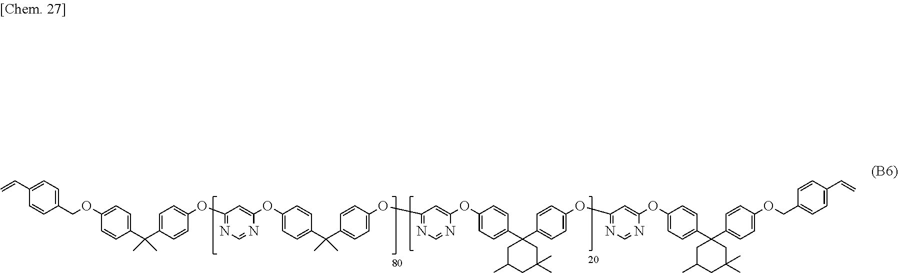

### [Synthesis Example 7] Synthesis of Polymer (B7)

Into a four-necked flask, 162.23 mmol of 4,4′-(hexafluoroisopropylidene)diphthalic anhydride as an acid dianhydride, 175.39 mmol of 2,2-bis[4-(4-aminophenoxy)phenyl]propane as a diamine, and N-methyl-2 pyrrolidone (2.0 g with respect to 1 mmol of the total amount of the acid dianhydride and the diamine) as a polymerization solvent were charged. After the inside of the flask was replaced with nitrogen, the contents of the flask were heated at 40° C. for 4 hours and then further heated at 180° C. for 4 hours. After the contents of the flask were cooled to room temperature, 420.94 mmol of 4-(chloromethyl)styrene as a reactive group Y modifier and 420.94 mmol of potassium carbonate as an alkali metal compound were added, and the contents of the flask was heated at 40° C. for 4 hours. After the contents of the flask were cooled to room temperature, the precipitated solid was separated by filtration, methanol was added to the filtrate, the precipitated solid was washed with methanol, and these solids were dried, thereby obtaining a polymer (B7). The obtained polymer (B7) was analyzed by, for example, ¹³C-NMR and revealed that it was a polymer having a structure represented by Formula (B7). The weight average molecular weight (Mw) of the polymer (B7) was 19,000.

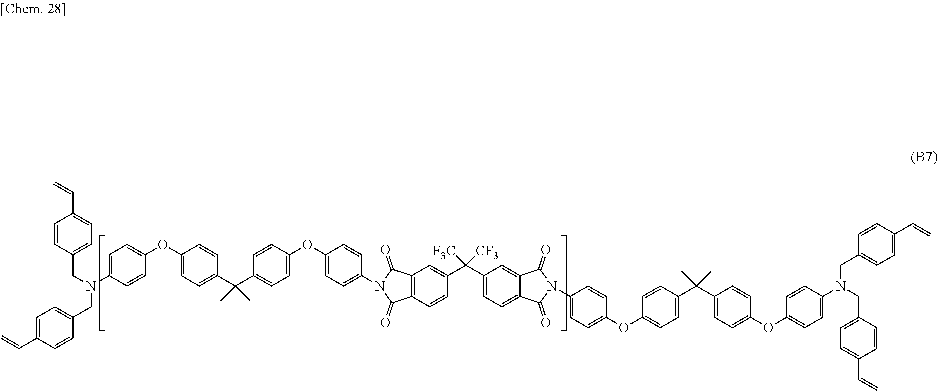

### [Synthesis Example 8] Synthesis of Polymer (RB1)

Into a four-necked flask, 171.56 mmol of 4,6-dichloropvrimidine as a haloaen compound, 150.00 mmol of bisphenol A and 37.50 mmol of 1,1-bis(4-hydroxyphenyl)-3,3,5-trimethylcyclohexane as phenol compounds, 231.61 mmol of potassium carbonate as an alkali metal compound, and N-methyl-2 pyrrolidone (0.5 g with respect to 1 mmol of the total amount of the halogen compound, the phenol compounds, and the reactive group Y modifier) as a polymerization solvent were charged. After the inside of the flask was replaced with nitrogen, the contents of the flask were heated at 130° C. for 6 hours, and water generated during the heating was removed from the Dean-Stark tube as needed. After the contents of the flask were cooled to room temperature, the precipitated solid was separated by filtration, methanol was added to the filtrate, the precipitated solid was washed with methanol, and these solids were dried, thereby obtaining a polymer (RB1). The obtained polymer (RB1) was analyzed by, for example, ¹³C-NMR and revealed that it was a polymer having a structure represented by Formula (RB1). The weight average molecular weight (Mw) of the polymer (RB1) was 12,000.

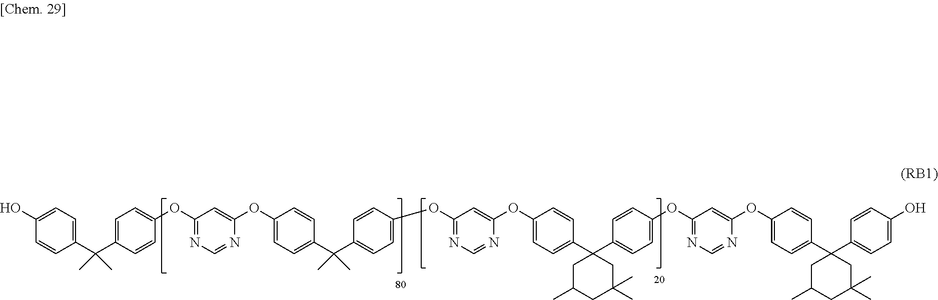

The types and amounts of the monomers used in Synthesis Examples 1 to 8 and the weight average molecular weights (Mw) of the obtained polymers are shown in Table 1.

TABLE 1

| | | Halogen compound | | Phenol compound | | | Reactive group Y modifier | | | |
|---|---|---|---|---|---|---|---|---|---|---|
| Polyether | Polymer | Type | Amount | Type | Amount | | Type | Amount | | Mw |
| Synthesis | (B1) | 4,6- | 177.65 mmol | Bisphenol A | 153.00 | mmol | 4-Hydroxy-α- | 17.00 | mmol | 14,000 |
| Example 1 | | Dichloropyrimidine | | 1,1-Bis(4-hydroxyphenyl)- | 17.00 | mmol | methylstyrene | | | |
| | | | | 3,3,5-trimethylcyclohexane | | | | | | |
| Synthesis | (B6) | 4,6- | 171.56 mmol | Bisphenol A | 150.00 | mmol | 4-(Chloro- | 150.00 | mmol | 12,000 |
| Example 6 | | Dichloropyrimidine | | 1,1-Bis(4-hydroxyphenyl)- | 37.50 | mmol | methyl)styrene | | | |
| | | | | 3,3,5-trimethylcyclohexane | | | | | | |
| Synthesis | (RB1) | 4,6- | 171.56 mmol | Bisphenol A | 150.00 | mmol | — | — | | 12,000 |
| Example 8 | | Dichloropyrimidine | | 1,1-Bis(4-hydroxyphenyl)- | 37.50 | mmol | | | | |
| | | | | 3,3,5-trimethylcyclohexane | | | | | | |

| Polyimide | | Acid dianhydride | | Diamine |
|---|---|---|---|---|
| (precursor) | Polymer | Type | Amount | Type |
| Synthesis | (B2) | 4,4′-(Hexafluoroisopropyl- | 153.46 mmol | 2,2-Bis[4-(4- |
| Example 2 | | idene)diphthalic anhydride | | aminophenoxy)phenyl]propane |
| Synthesis | (B3) | Pyromellitic anhydride | 157.31 mmol | 4,4′-Diaminodiphenyl ether |
| Example 3 | | | | |
| Synthesis | (B4) | 4,4′-(Hexafluoroisopropyl- | 162.23 mmol | 2,2-Bis[4-(4-amino- |
| Example 4 | | idene)diphthalic anhydride | | phenoxy)phenyl]propane |
| Synthesis | (B5) | 4,4′-(4,4′- | 173.04 mmol | 2,2-Bis[4-(4-amino- |
| Example 5 | | Isopropylidenediphenoxy)diphthalic | | phenoxy)phenyl]propane |
| | | anhydride | | |
| Synthesis | (B7) | 4,4′-(Hexafluoroisopropyl- | 162.23 mmol | 2,2-Bis[4-(4-amino- |
| Example 7 | | idene)diphthalic anhydride | | phenoxy)phenyl]propane |

| Polyimide | Diamine | Reactive group Y modifier | | |
|---|---|---|---|---|
| (precursor) | Amount | Type | Amount | Mw |
| Synthesis | 170.52 mmol | 3-Isopropenyl-α,α- | 170.52 mmol | 24,000 |
| Example 2 | | dimethylbenzyl isocyanate | | |
| Synthesis | 174.79 mmol | 3-Isopropenyl-α,α- | 174.79 mmol | 21,000 |
| Example 3 | | dimethylbenzyl isocyanate | | |
| Synthesis | 175.39 mmol | 2-Isocyanatoethyl | 105.23 mmol | 27,000 |
| Example 4 | | methacrylate | | |
| Synthesis | 181.69 mmol | 2-Hydroxyethyl | 346.07 mmol | 20,000 |
| Example 5 | | methacrylate | | |
| Synthesis | 175.39 mmol | 4-(Chloromethyl)styrene | 420.94 mmol | 19,000 |
| Example 7 | | | | |

### [Synthesis Example 9] Synthesis of Polyfunctional Styryl Compound (A2-1

Into a four-necked flask, 157.69 mmol of bisphenol A as a phenol compound, 946.17 mmol of 4-(chloromethyl)styrene as a halogen compound, 946.17 mmol of potassium carbonate as an alkali metal compound, and N-methyl-2-pyrrolidone (0.5 g per 1 mmol of the total amount of the halogen compound and the phenol compound) as a synthetic solvent were charged. After the inside of the flask was replaced with nitrogen, the contents of the flask were heated at 80° C. for 4 hours. After the contents of the flask were cooled to room temperature, then the precipitated solid was separated by filtration, methanol was added to the filtrate, the precipitated solid was washed with methanol, and these solids were dried, thereby obtaining a polyfunctional styryl compound (A2-1). The obtained compound (A2-1) was analyzed by, for example, ¹³C-NMR and revealed that it was a polymer having a structure represented by Formula (A2-1).

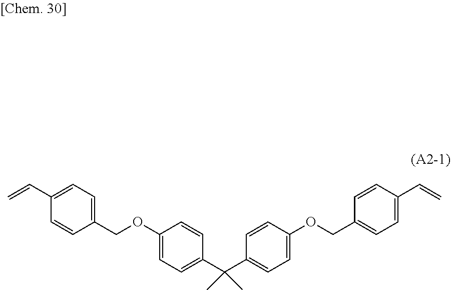 [SMILES: C=Cc1ccc(COc2ccc(C(C)(C)c3ccc(OCc4ccc(C=C)cc4)cc3)cc2)cc1]

### [Synthesis Example 10] Synthesis of Polyfunctional Styryl Compound (A2-2

Into a four-necked flask, 151.66 mmol of 4,6-dihydroxypyrimidine as a phenol compound, 909.98 mmol of 4-(chloromethyl)styrene as a halogen compound, 909.98 mmol of potassium carbonate as an alkali metal compound, and N-methyl-2-pyrrolidone (0.5 g per 1 mmol of the total amount of the halogen compound and the phenol compound) as a synthetic solvent were charged. After the inside of the flask was replaced with nitrogen, the contents of the flask were heated at 80° C. for 4 hours. After the contents of the flask were cooled to room temperature, then the precipitated solid was separated by filtration, methanol was added to the filtrate, the precipitated solid was washed with methanol, and these solids were dried, thereby obtaining a polyfunctional styryl compound (A2-2). The obtained compound (A2-2) was analyzed by, for example, ¹³C-NMR and revealed that it was a polymer having a structure represented by Formula (A2-2).

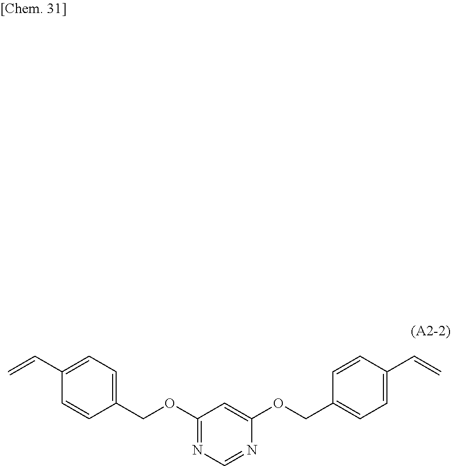 [SMILES: C=Cc1ccc(COc2cc(OCc3ccc(C=C)cc3)ncn2)cc1]

### <Preparation of Radiation-Sensitive Composition>

### Examples and Comparative Examples

The polyfunctional maleimide compounds, the polyfunctional styryl compounds, the polymers, the photopolymerization initiators, and other components shown in Tables 2-1 to 2-3 (hereinafter, collectively referred to as “Table 2”) were uniformly mixed in the amounts shown in Table 2 using the organic solvents shown in Table 2 so as to have the solid content concentrations shown in Table 2, thereby preparing radiation-sensitive compositions of Examples 1 to 16 and Comparative Examples 1 to 5. The obtained radiation-sensitive compositions were evaluated as follows. The results are shown in Table 2.

### <<Resolution>>

The radiation-sensitive composition was spin-coated on a 6 inch silicon wafer, and then heating was performed at 110° C. for 5 minutes using a hot plate, thereby preparing a coating film (film thickness: 10 μm). Next, the coating film was exposed to ultraviolet rays from a high-pressure mercury lamp through a photomask using an aligner (Model “MA-150” manufactured by Suss Microtec SE) so that the exposure dose at a wavelength of 365 nm was 500 mJ/cm². Subsequently, dip development was performed at 23° C. for 3 minutes using a developer (cyclopentanone). The coating film after development was heated in a nitrogen atmosphere under heating conditions (curing temperature and curing time) shown in Table 2 using an oven to produce a resin film having a pattern. The produced resin film having a pattern was observed with an electron microscope and evaluated according to the following criteria.
◯: A square pattern having a length of 50 μm and a width of 50 μm was formed.
X: A square pattern having a length of 50 μm and a width of 50 μm was not formed.

### <<Elongation>>

The radiation-sensitive composition was applied onto a substrate with a release material, and then, heating was performed at 110° C. for 5 minutes using an oven, thereby preparing a coating film. Next, the entire surface of the coating film was exposed to ultraviolet rays from a high-pressure mercury lamp using an aligner (model “MA-150” manufactured by Suss Microtec SE) so that the exposure dose at a wavelength of 365 nm was 500 mJ/cm². Next, heating was performed in a nitrogen atmosphere under heating conditions (curing temperature and curing time) shown in Table 2 using an oven.

The coating film heated by post-baking was peeled off from the substrate with a release material to obtain a resin film having a thickness of 15 μm. The obtained resin film was cut into a strip shape of 5 cm long×0.5 cm wide. A tensile elongation at break (%) of the strip-shaped resin film was measured by a tensile compression tester (product name “SDWS-0201 type” manufactured by IMADA-SS Corporation). The measurement conditions are chuck distance=2.5 cm, pulling speed=5 mm/min, and measurement temperature=23° C. The average value of the five measured values was defined as an “elongation (initial value)”, and evaluation was performed according to the following criteria.
◯: The elongation was 20% or more.
Δ: The elongation was 10% or more.
X: The elongation was less than 10% and unmeasurable.

The tensile test piece prepared above was subjected to atmospheric reflow (maximum temperature 260° C.) 3 times, and then exposed to an environment of 130° C./85% RH/96 hr. The tensile elongation of the test piece after exposure was measured in the same manner as in the elongation (initial value), and the measured value was defined as an “elongation (after PCT test)”.

From the elongation (initial value) and the elongation (after the PCT test) measured above, the “elongation retention rate” was calculated by the following formula:

$${‶}^{} Elongation {( after PCT test )}^{″} {/}^{‶} Elongation {( initial value )}^{″} \times 100 = Elongation Retention Rate ( \% )$$

and evaluated according to the following criteria.
◯: The retention rate was 70% or more.
Δ: The retention rate was 50% or more.
X: The retention rate was less than 50% and unmeasurable.

### <<Dielectric Properties>>

The radiation-sensitive composition was applied onto a substrate with a release material, and then, heating was performed at 110° C. for 5 minutes using an oven, thereby preparing a coating film. Next, the entire surface of the coating film was exposed to ultraviolet rays from a high-pressure mercury lamp using an aligner (model “MA-150” manufactured by Suss Microtec SE) so that the exposure dose at a wavelength of 365 nm was 500 mJ/cm². Next, heating was performed in a nitrogen atmosphere under heating conditions (curing temperature and curing time) shown in Table 2 using an oven.

The coating film heated by post-baking was peeled off from the substrate with a release material to obtain a resin film having a thickness of 10 μm. The relative dielectric constant (εᵣ) and dielectric loss tangent (tan δ) of the obtained resin film at 10 GHz were measured by a cavity resonator perturbation method using a dielectric property measuring apparatus (cavity resonator for 10 GHz manufactured by Kanto Electronic Application and Development Inc.) under the conditions of 23° C. and a relative humidity of 50% RH.

TABLE 2-1

| Component | | Example 1 | Example 2 | Example 3 | Example 4 | Example 5 | Example 6 | Example 7 | Example 8 |
|---|---|---|---|---|---|---|---|---|---|
| Polyfunctional maleimide compound (A-1) | A1-1 | 20 | — | — | — | — | — | — | — |
| (parts by mass) | A1-2 | — | 20 | — | — | — | — | 20 | — |
| | A1-3 | — | — | 20 | — | — | — | — | 20 |
| | A1-4 | — | — | — | 20 | 20 | 20 | — | — |
| Polyfunctional styryl compound (A-2) | A2-1 | — | — | — | — | — | — | — | — |
| (parts by mass) | A2-2 | — | — | — | — | — | — | — | — |
| Polymer (B) | B1 | 100 | 100 | 100 | 100 | — | — | — | — |
| (parts by mass) | B2 | — | — | — | — | 100 | — | — | — |
| | B3 | — | — | — | — | — | 100 | — | — |
| | B4 | — | — | — | — | — | — | 100 | — |
| | B5 | — | — | — | — | — | — | — | 100 |
| | B6 | — | — | — | — | — | — | — | — |
| | B7 | — | — | — | — | — | — | — | — |
| | RB1 | — | — | — | — | — | — | — | — |
| | RB2 | — | — | — | — | — | — | — | — |
| Photopolymerization | C1 | 3 | 3 | 3 | 3 | 3 | 3 | 3 | 3 |
| initiator (C) (parts by mass) | | | | | | | | | |
| Surfactant (D) (parts by mass) | D1 | 0.05 | 0.05 | 0.05 | 0.05 | 0.05 | 0.05 | 0.05 | 0.05 |
| Other components | F1 | — | — | — | — | — | — | — | — |
| (parts by mass) | F2 | — | — | — | — | — | — | — | — |
| | F3 | — | — | — | — | — | — | — | — |
| | F4 | — | — | — | — | — | — | — | — |
| Solvent | E1 | 100 | 100 | 100 | 100 | — | — | — | — |
| (solvent composition, mass %) | E2 | — | — | — | — | 100 | 100 | 100 | 100 |

| Solid content concentration (mass %) | 37 | | 36 | | 37 | | 37 | | 37 | | 37 | | 37 | | 37 | |
|---|---|---|---|---|---|---|---|---|---|---|---|---|---|---|---|---|
| Curing temperature | 230° | C. | 230° | C. | 230° | C. | 230° | C. | 230° | C. | 230° | C. | 230° | C. | 230° | C. |
| Curing time | 4 | hr | 4 | hr | 4 | hr | 4 | hr | 4 | hr | 4 | hr | 4 | hr | 4 | hr |

| | | | | | | | | |
|---|---|---|---|---|---|---|---|---|
| Resolution | ◯ | ◯ | ◯ | ◯ | ◯ | ◯ | ◯ | ◯ |
| Elongation (initial value) | ◯ | ◯ | ◯ | ◯ | ◯ | ◯ | ◯ | Δ |
| Elongation retention rate | ◯ | ◯ | ◯ | ◯ | ◯ | ◯ | ◯ | ◯ |
| Relative dielectric constant @10 GHz | 2.8 | 2.9 | 2.8 | 2.8 | 2.9 | 3.1 | 2.9 | 3.0 |
| Dielectric loss tangent @10 GHz | 0.005 | 0.005 | 0.004 | 0.004 | 0.004 | 0.008 | 0.004 | 0.008 |

TABLE 2-2

| Component | | Example 9 | Example 10 | Example 11 | Example 12 | Example 13 | Example 14 | Example 15 | Example 16 |
|---|---|---|---|---|---|---|---|---|---|
| Polyfunctional | A1-1 | — | — | — | — | — | — | — | — |
| maleimide compound (A-1) | A1-2 | — | 5 | 5 | 15 | 10 | — | 15 | 15 |
| (parts by mass) | A1-3 | 5 | — | — | — | — | — | — | — |
| | A1-4 | — | — | — | — | — | — | — | — |
| Polyfunctional | A2-1 | — | 10 | 10 | — | 5 | 15 | — | — |
| styryl compound (A-2) | A2-2 | — | — | — | — | — | — | — | 5 |
| (parts by mass) | | | | | | | | | |
| Polymer (B) | B1 | — | 100 | — | — | — | — | — | — |
| (parts by mass) | B2 | — | — | — | — | — | — | — | — |
| | B3 | — | — | — | — | — | — | — | — |
| | B4 | — | — | — | — | — | — | — | 100 |
| | B5 | 100 | — | — | — | — | — | — | — |
| | B6 | — | — | 100 | 100 | 100 | 100 | — | — |
| | B7 | — | — | — | — | — | — | 100 | — |
| | RB1 | — | — | — | — | — | — | — | — |
| | RB2 | — | — | — | — | — | — | — | — |
| Photopolymerization | C1 | 3 | 3 | 3 | 3 | 3 | 3 | 3 | 3 |
| initiator (C) (parts by mass) | | | | | | | | | |
| Surfactant (D) (parts by mass) | D1 | 0.05 | 0.05 | 0.05 | 0.05 | 0.05 | 0.05 | 0.05 | 0.05 |
| Other components | F1 | — | — | — | — | — | — | — | — |
| (parts by mass) | F2 | — | — | — | — | — | — | — | — |
| | F3 | — | — | — | — | — | — | — | — |
| | F4 | — | — | — | — | — | — | — | — |
| Solvent (solvent | E1 | — | 100 | 100 | 100 | 100 | 100 | — | — |
| composition, mass %) | E2 | 100 | — | — | — | — | — | 100 | 100 |

| Solid content concentration (mass %) | 37 | | 37 | | 37 | | 37 | | 37 | | 37 | | 37 | | 37 | |
|---|---|---|---|---|---|---|---|---|---|---|---|---|---|---|---|---|
| Curing temperature | 230° | C. | 230° | C. | 230° | C. | 230° | C. | 230° | C. | 230° | C. | 230° | C. | 230° | C. |
| Curing time | 4 | hr | 4 | hr | 4 | hr | 4 | hr | 4 | hr | 4 | hr | 4 | hr | 4 | hr |

| | | | | | | | | |
|---|---|---|---|---|---|---|---|---|
| Resolution | ◯ | ◯ | ◯ | ◯ | ◯ | ◯ | ◯ | ◯ |
| Elongation (initial value) | ◯ | ◯ | ◯ | ◯ | ◯ | ◯ | ◯ | ◯ |
| Elongation retention rate | ◯ | ◯ | ◯ | ◯ | ◯ | ◯ | ◯ | ◯ |
| Relative dielectric constant @10 GHz | 3.0 | 2.7 | 2.7 | 2.7 | 2.7 | 2.7 | 2.8 | 2.9 |
| Dielectric loss tangent @10 GHz | 0.007 | 0.005 | 0.005 | 0.004 | 0.004 | 0.004 | 0.007 | 0.006 |

TABLE 2-3

| | | Comparative | Comparative | Comparative | Comparative | Comparative |
|---|---|---|---|---|---|---|
| Component | | Example 1 | Example 2 | Example 3 | Example 4 | Example 5 |
| Polyfunctional maleimide compound (A-1) | A1-1 | — | — | — | — | — |
| (parts by mass) | A1-2 | — | 20 | 20 | — | — |
| | A1-3 | — | — | — | — | — |
| | A1-4 | — | — | — | — | — |
| Polyfunctional styryl compound (A-2) | A2-1 | — | — | — | — | — |
| (parts by mass) | A2-2 | — | — | — | — | — |
| Polymer (B) | B1 | — | — | — | 100 | 100 |
| (parts by mass) | B2 | — | — | — | — | — |
| | B3 | — | — | — | — | — |
| | B4 | — | — | 100 | — | — |
| | B5 | — | — | — | — | — |
| | B6 | — | — | — | — | — |
| | B7 | — | — | — | — | — |
| | RB1 | 100 | — | — | — | — |
| | RB2 | — | 100 | — | — | — |
| Photopolymerization initiator (C) (parts by mass) | C1 | — | 3 | — | 3 | — |
| Surfactant (D) (parts by mass) | D1 | 0.05 | 0.05 | 0.05 | 0.05 | 0.05 |
| Other components | F1 | — | — | — | 15 | 15 |
| (parts by mass) | F2 | 20 | — | — | — | — |
| | F3 | 3 | — | — | — | — |
| | F4 | 0.5 | — | — | — | — |
| Solvent | E1 | 100 | 100 | — | 100 | 100 |
| (solvent composition, mass %) | E2 | — | — | 100 | — | — |

| Solid content concentration (mass %) | 38 | | 37 | | 37 | | 37 | | 37 | |
|---|---|---|---|---|---|---|---|---|---|---|
| Curing temperature | 230° | C. | 230° | C. | 230° | C. | 230° | C. | 230° | C. |
| Curing time | 4 | hr | 4 | hr | 4 | hr | 4 | hr | 4 | hr |

| | | | | | |
|---|---|---|---|---|---|
| Resolution | ◯ | X | X | ◯ | X |
| Elongation (initial value) | ◯ | X | X | X | X |
| Elongation retention rate | X | X | X | X | X |
| Relative dielectric constant @10 GHz | 2.8 | — | — | 2.8 | — |
| Dielectric loss tangent @10 GHz | 0.006 | — | — | 0.007 | — |

The respective components in Table 2 are as follows.
(A1-1): Polyfunctional maleimide compound represented by the following Formula (A1-1) (“BMI-2000” manufactured by Daiwa Kasei Industry Co., Ltd.)
(A1-2): Polyfunctional maleimide compound represented by the following Formula (A1-2) (“BMI-2300” manufactured by Daiwa Kasei Industry Co., Ltd.)
(A1-3): Polyfunctional maleimide compound represented by the following Formula (A1-3) (“BMI-4000” manufactured by Daiwa Kasei Industry Co., Ltd.)
(A1-4): Polyfunctional maleimide compound represented by the following Formula (A1-4) (“MIR-3000” manufactured by Nippon Kayaku Co., Ltd.)

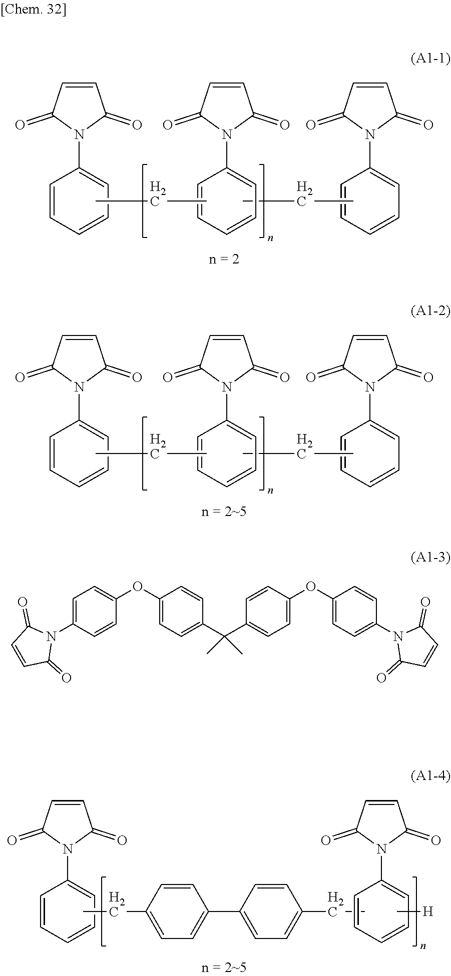

(A2-1): Polyfunctional styryl compound (A2-1) synthesized in Synthesis Example 9
(A2-2): Polyfunctional styryl compound (A2-2) synthesized in Synthesis Example 10
(B1): Polymer (B1) polymerized in Synthesis Example 1
(B2): Polymer (B2) polymerized in Synthesis Example 2
(B3): Polymer (B3) polymerized in Synthesis Example 3
(B4): Polymer (B4) polymerized in Synthesis Example 4
(B5): Polymer (B5) polymerized in Synthesis Example 5
(B6): Polymer (B6) polymerized in Synthesis Example 6
(B7): Polymer (B7) polymerized in Synthesis Example 7
(RB1): Polymer (RB1) polymerized in Synthesis Example 8
(RB2): Cresol novolac resin composed of m-cresol/p-cresol=60/40 (molar ratio) (Mw=6,500)
(C1): “Irgacure OXE02” manufactured by BASF SE
(D1): Fluorine-based surfactant (“NBX-15” manufactured by Neos Corporation)
(E1): Cyclohexanone
(E2): Gamma-butyrolactone
(F1): Polyfunctional acrylate (“NK Ester A-9300” manufactured by SHIN-NAKAMURA CHEMICAL CO, LTD.)
(F2): Hexamethoxymethylated melamine (“CYMEL 300” manufactured by Mitsui Chemicals, Inc.)
(F3): Photoacid generator shown below
(F4): 1,2,3-Benzotriazole

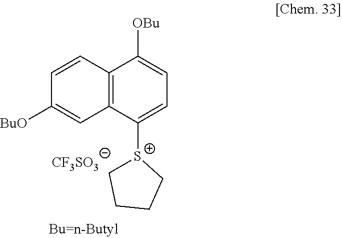

1. A radiation-sensitive composition for forming an insulation film, comprising:
at least one polyfunctional compound (A) selected from the group consisting of a polyfunctional maleimide compound (A-1) and a polyfunctional styryl compound (A-2);
a polymer (B) having a group Y that reacts with a maleimide group in the polyfunctional maleimide compound (A-1) or a styryl group in the polyfunctional styryl compound (A-2); and
a photopolymerization initiator (C),
wherein the polymer (B) is a polymer having a repeating structural unit represented by Formula (a2), and
the group Y is represented by Formula (Y1), 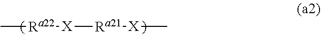
wherein, in Formula (a2), two X's each independently represent a single bond, an oxygen atom, a sulfur atom, an amide bond, —NH—C(O)—NH—, or —SO₂—, and at least one X represents an oxygen atom, a sulfur atom, an amide bond, —NH—C(O)—NH—, or —SO₂—,
R^{a21} represents a divalent hydrocarbon group or a divalent group in which a hydrogen atom in the divalent hydrocarbon group is substituted with a functional group other than a heterocyclic ring,
R^{a22} represents a divalent hydrocarbon group, a divalent group in which a hydrogen atom in the divalent hydrocarbon group is substituted with a functional group other than a heterocyclic ring, or a heterocyclic ring-containing group, and
R^{a21} and R^{a22} each optionally have the group Y, 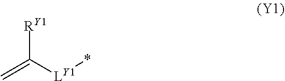
wherein, in Formula (Y1), R^{Y1} represents a hydrogen atom or an alkyl group having 1 to 5 carbon atoms, L^{Y1} represents a single bond, an alkanediyl group having 1 to 5 carbon atoms, —C(O)O—, —NH—C(O)—NH—, or a group obtained by a combination thereof, and * represents a position bonded to a main chain or a side chain of the polymer (B).

2. A radiation-sensitive composition for forming an insulation film, comprising:
a polyfunctional maleimide compound (A-1);
a polymer (B) having a group Y that reacts with a maleimide group in the polyfunctional maleimide compound (A-1); and
a photopolymerization initiator (C),
wherein the polymer (B) is a polymer having a repeating structural unit represented by Formula (a2), and
the group Y is represented by Formula (Y1), 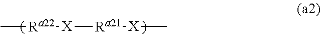
wherein, in Formula (a2), two X's each independently represent a single bond, an oxygen atom, a sulfur atom, an amide bond, —NH—C(O)—NH—, or —SO₂—, and at least one X represents an oxygen atom, a sulfur atom, an amide bond, —NH—C(O)—NH—, or —SO₂—,
R^{a21} represents a divalent hydrocarbon group or a divalent group in which a hydrogen atom in the divalent hydrocarbon group is substituted with a functional group other than a heterocyclic ring,
R^{a22} represents a divalent hydrocarbon group, a divalent group in which a hydrogen atom in the divalent hydrocarbon group is substituted with a functional group other than a heterocyclic ring, or a heterocyclic ring-containing group, and
R^{a21} and R^{a22} each optionally have the group Y, 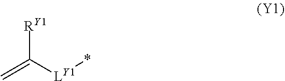
wherein, in Formula (Y1), R^{Y1} represents a hydrogen atom or an alkyl group having 1 to 5 carbon atoms, L^{Y1} represents a single bond, an alkanediyl group having 1 to 5 carbon atoms, —C(O)O—, —NH—C(O)—NH—, or a group obtained by a combination thereof, and * represents a position bonded to a main chain or a side chain constituting the polymer (B).

3. The radiation-sensitive composition for forming an insulation film according to claim 2, further comprising a polyfunctional styryl compound (A-2).

4. The radiation-sensitive composition for forming an insulation film according to claim 1, wherein the polyfunctional maleimide compound (A-1) has three or more maleimide groups.

5. The radiation-sensitive composition for forming an insulation film according to claim 1, wherein the polyfunctional maleimide compound (A-1) has a phenolic hydroxyl group.

6. The radiation-sensitive composition for forming an insulation film according to claim 1, wherein the polymer (B) is a polyimide, a polyimide precursor, a polybenzoxazole, a polybenzoxazole precursor, or a polyphenylene ether.

7. The radiation-sensitive composition for forming an insulation film according to claim 1, wherein the polymer (B) has the group Y at a terminal thereof.

8. The radiation-sensitive composition for forming an insulation film according to claim 1, wherein R^{a21} is an arylene group.

9. The radiation-sensitive composition for forming an insulation film according to claim 1, wherein R^{a22} is a divalent group obtained by removing two hydrogen atoms from pyrimidine, or an arylene group.

10. A method for producing a resin film having a pattern, the method comprising:
forming, on a substrate, a coating film by applying the radiation-sensitive composition for forming an insulation film according to claim 1;
selectively exposing the coating film; and
developing the exposed coating film with a developer comprising an organic solvent.

11. A resin film having a pattern obtained by curing the radiation-sensitive composition for forming an insulation film according to claim 1.

12. A semiconductor circuit board comprising the resin film having a pattern according to claim 11.
